(19) United States
(12) Patent Application Publication
(10) Pub. No.: US 2026/0362745 A1
(43) Pub. Date: Nov. 12, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yun Ju FAN, Hsinchu (TW); Lo-Heng CHANG, Hsinchu (TW); Huan-Chieh SU, Tianzhong (TW); Chih-Hao WANG, Baoshan (TW)

(73) Assignee: Taiwan Semiconductor Manufacturing Company, Ltd., Hsinchu (TW)

(21) Appl. No.: 19/747,033

(22) Filed: Jul. 20, 2026

Related U.S. Application Data
(63) Continuation of application No. 19/015,173, filed on Jan. 9, 2025.
(60) Provisional application No. 63/684,716, filed on Aug. 19, 2024.

(51) Int. Cl. H10D 30/67; H10D 30/00; H10D 30/01; H10D 30/43; H10D 62/10; H10D 62/13; H10D 84/03; H10D 84/83

(52) U.S. Cl. CPC H10D 30/6735; H10D 30/014; H10D 30/0191; H10D 30/43; H10D 30/502; H10D 62/121; H10D 62/151; H10D 84/038; H10D 84/832

(57) ABSTRACT

A method of manufacturing a semiconductor device includes forming a semiconductor device structure including a gate structure and source/drain regions disposed over a substrate, wherein the source/drain regions are embedded in the semiconductor device structure. An opening is formed in the semiconductor device structure over the source/drain region. A dopant is implanted into sidewalls of the opening. The opening is enlarged over the source/drain region. The source/drain region is exposed. A silicide layer is formed over the exposed source/drain region, and a conductive contact is formed in the opening.

### RELATED APPLICATION

This application is a continuation application of U.S. patent application Ser. No. 19/015,173 filed Jan. 9, 2025, which claims priority to U.S. Provisional Application No. 63/684,716 filed Aug. 19, 2024, the entire disclosure of each of which is incorporated herein by reference.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET) including a fin FET (FinFET) and a gate-all-around (GAA) FET. In a FinFET, a gate electrode is adjacent to three side surfaces of a channel region with a gate dielectric layer interposed therebetween. Because the gate structure surrounds (wraps) the fin on three surfaces, the transistor essentially has three gates controlling the current through the fin or channel region. In a GAA FET, all side surfaces of the channel region are surrounded by the gate electrode, which allows for fuller depletion in the channel region and result in less short-channel effects due to steeper sub-threshold current swing (SS) and smaller drain induced barrier lowering (DIBL). As transistor dimensions are continually scaled down to sub 20-25 nm technology nodes, further improvements of the GAA FET are required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a cross sectional view of one of the various stages of manufacturing a GAA FET semiconductor device according to an embodiment of the present disclosure.

FIG. 2A shows a cross sectional view and FIG. 2B shows an isometric view of one of the various stages of manufacturing a GAA FET semiconductor device according to embodiments of the present disclosure.

FIG. 3A shows a cross sectional view and FIG. 3B shows an isometric view of one of the various stages of manufacturing a GAA FET semiconductor device according to embodiments of the present disclosure.

FIG. 4 shows a cross sectional view of one of the various stages of manufacturing a GAA FET semiconductor device according to an embodiment of the present disclosure.

FIG. 5 shows a cross sectional view of one of the various stages of manufacturing a GAA FET semiconductor device according to an embodiment of the present disclosure.

FIG. 6 shows a cross sectional view of one of the various stages of manufacturing a GAA FET semiconductor device according to an embodiment of the present disclosure.

FIG. 7 shows a cross sectional view of one of the various stages of manufacturing a GAA FET semiconductor device according to an embodiment of the present disclosure.

FIG. 8 shows a cross sectional view of one of the various stages of manufacturing a GAA FET semiconductor device according to an embodiment of the present disclosure.

FIGS. 9A, 9B, and 9C show cross sectional views of various stages of manufacturing a GAA FET semiconductor device according to embodiments of the present disclosure.

FIGS. 10A and 10B show cross sectional views of various stages of manufacturing a GAA FET according to embodiments of the disclosure. FIG. 10C shows an isometric view of one of the various stages of manufacturing a GAA FET semiconductor device according to an embodiment of the present disclosure.

FIG. 11 shows a cross sectional view of one of the various stages of manufacturing a GAA FET semiconductor device according to an embodiment of the present disclosure.

FIG. 12 shows a cross sectional view of one of the various stages of manufacturing a GAA FET semiconductor device according to an embodiment of the present disclosure.

FIG. 13 shows a cross sectional view of one of the various stages of manufacturing a GAA FET semiconductor device according to an embodiment of the present disclosure.

FIG. 14A and FIG. 14B respectively show an isometric view and a cross sectional view of one of the various stages of manufacturing a GAA FET semiconductor device according to an embodiment of the present disclosure.

FIG. 15A and FIG. 15B respectively show an isometric view and a cross sectional view of one of the various stages of manufacturing a GAA FET semiconductor device according to an embodiment of the present disclosure.

FIG. 16A and FIG. 16B respectively show an isometric view and a cross sectional view of one of the various stages of manufacturing a GAA FET semiconductor device according to an embodiment of the present disclosure.

FIG. 17A shows an isometric view of one of the various stages of manufacturing a GAA FET semiconductor device according to an embodiment of the present disclosure. FIG. 17B shows a detailed isometric view of a portion of FIG. 17A. FIG. 17C shows a cross sectional view of one of the various stages of manufacturing a GAA FET semiconductor device according to an embodiment of the present disclosure.

FIG. 18A shows an isometric view of one of the various stages of manufacturing a GAA FET semiconductor device according to an embodiment of the present disclosure. FIG. 18B shows a detailed isometric view of a portion of FIG. 18A.

FIG. 19A shows an isometric view of one of the various stages of manufacturing a GAA FET semiconductor device according to an embodiment of the present disclosure. FIG. 19B shows a detailed isometric view of a portion of FIG. 19A. FIG. 19C shows a cross sectional view of one of the various stages of manufacturing a GAA FET semiconductor device according to an embodiment of the present disclosure.

FIG. 20A shows an isometric view of one of the various stages of manufacturing a GAA FET semiconductor device according to an embodiment of the present disclosure. FIG. 20B shows a detailed isometric view of a portion of FIG. 20A. FIG. 20C shows a cross sectional view of one of the various stages of manufacturing a GAA FET semiconductor device according to an embodiment of the present disclosure.

FIG. 21A shows an isometric view of one of the various stages of manufacturing a GAA FET semiconductor device according to an embodiment of the present disclosure. FIG. 21B shows a detailed isometric view of a portion of FIG. 21A. FIG. 21C shows a cross sectional view of one of the various stages of manufacturing a GAA FET semiconductor device according to an embodiment of the present disclosure.

FIGS. 22A and 22B show cross sectional views of various stages of manufacturing a GAA FET semiconductor device according to embodiments of the present disclosure.

FIG. 23A and FIG. 23B respectively show an isometric view and a cross sectional view of one of the various stages of manufacturing a GAA FET semiconductor device according to an embodiment of the present disclosure.

FIG. 24A and FIG. 24B respectively show an isometric view and a cross sectional view of one of the various stages of manufacturing a GAA FET semiconductor device according to an embodiment of the present disclosure.

FIG. 25A and FIG. 25B respectively show an isometric view and a cross sectional view of one of the various stages of manufacturing a GAA FET semiconductor device according to an embodiment of the present disclosure.

FIG. 26A and FIG. 26B respectively show an isometric view and a cross sectional view of one of the various stages of manufacturing a GAA FET semiconductor device according to an embodiment of the present disclosure.

FIG. 27A and FIG. 27B respectively show a detailed isometric view and a detailed cross sectional view of one of the various stages of manufacturing a GAA FET semiconductor device according to an embodiment of the present disclosure.

FIG. 28A and FIG. 28B respectively show a detailed isometric view and a detailed cross sectional view of one of the various stages of manufacturing a GAA FET semiconductor device according to an embodiment of the present disclosure.

FIG. 29A and FIG. 29B respectively show a detailed isometric view and a detailed cross sectional view of one of the various stages of manufacturing a GAA FET semiconductor device according to an embodiment of the present disclosure. FIGS. 29C, 29D, 29E, and 29F show detailed cross sectional views of other embodiments of manufacturing a GAA FET semiconductor device according to an embodiment of the present disclosure.

FIG. 30A and FIG. 30B respectively show a detailed isometric view and a detailed cross sectional view of one of the various stages of manufacturing a GAA FET semiconductor device according to an embodiment of the present disclosure.

FIG. 31A and FIG. 31B respectively show a detailed isometric view and a detailed cross sectional view of one of the various stages of manufacturing a GAA FET semiconductor device according to an embodiment of the present disclosure.

FIG. 32 shows a flow chart for a method of manufacturing a semiconductor device according to embodiments of the present disclosure.

FIG. 33 shows a flow chart for a method of manufacturing a semiconductor device according to embodiments of the present disclosure.

FIG. 34 shows a flow chart for a method of manufacturing a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. Source/drain structure(s) may refer to a source or a drain, individually or collectively dependent upon the context. In the following embodiments, materials, configurations, dimensions, processes and/or operations as described with respect to one embodiment (e.g., one or more figures) may be employed in the other embodiments, and detailed description thereof may be omitted.

Disclosed embodiments relate to a semiconductor device, in particular, gate-all-around field effect transistor (GAA FET) and a stacked channel FET having backside vias and their manufacturing methods.

As semiconductor devices are scaled down in size, the space for the backside vias becomes smaller, which increases the contact resistance of the backside contact. In embodiments of the disclosure, an enlarged backside via contact is provided that does not suffer from an increase in gate current leakage. Thus, semiconductor devices that can operate at higher power with increased efficiency are provided by embodiments of the present disclosure.

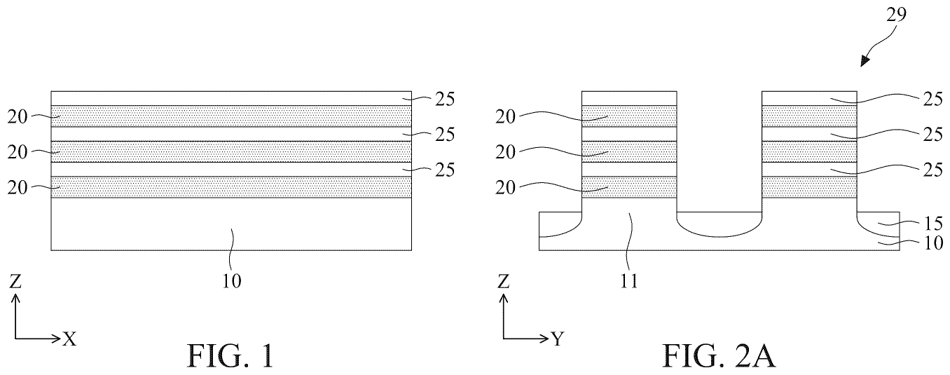

FIGS. 1 to 13 are schematic illustrations showing various stages of manufacturing a semiconductor FET device according to embodiments of the present disclosure. It is understood that additional operations can be provided before, during, and after processes shown by FIGS. 1-13, and some of the operations described below can be replaced or eliminated, for additional embodiments of the method. The order of the operations/processes may be interchangeable.

As shown in FIG. 1, first semiconductor layers 20 and second semiconductor layers 25 are alternately formed over a substrate 10. The first semiconductor layers 20 and the second semiconductor layers 25 are made of materials having different lattice constants, and may include one or more layers of Si, Ge, SiGe, GaAs, InSb, GaP, GaSb, InAlAs, InGaAs, GaSbP, GaAsSb or InP.

In some embodiments, the first semiconductor layers 20 and the second semiconductor layers 25 are made of Si, a Si compound, SiGe, Ge or a Ge compound. In some embodiments, the first semiconductor layers 20 are made of Si. In some embodiments, the first semiconductor layers 20 are made of Si₁₋ₓGeₓ, where x is equal to or more than about 0.1 and equal to or less than about 0.6, and the second semiconductor layers 25 are Si or Si_{1-y}Ge_{y}, where y is smaller than x and equal to or less than about 0.2. In this disclosure, an “M compound” or an “M based compound” means the majority of the compound is M.

In other embodiments, the second semiconductor layers 25 are made of Si₁₋ₓGeₓ, where x is equal to or more than about 0.1 and equal to or less than about 0.6, and the first semiconductor layers 20 are made of Si or Si_{1-y}Ge_{y}, where y is smaller than x and equal to or less than about 0.2.

In some embodiments, the second semiconductor layer 25 is made of the same material as the semiconductor substrate 10.

The thickness of the semiconductor layers 25 in the Z-direction is in a range from about 5 nm to about 60 nm and the width of the semiconductor layers 25 along the Y-direction is in a range from about 5 nm to about 80 nm in some embodiments. In some embodiments, the width of the semiconductor layers is greater than the thickness. In certain embodiments, the width is up to twice or five times the thickness of the semiconductor nanostructures 25.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb, and InP. The substrate 10 may include various regions that have been suitably doped with impurities (e.g., p-type or n-type conductivity). The dopants are, for example, boron difluoride (BF₂) for an n-type Fin FET and phosphorus for a p-type Fin FET in some embodiments. In certain embodiments, the substrate 10 is made of crystalline Si.

The substrate 10 may include in its surface region, one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

The first semiconductor layer 20 and the second semiconductor layer 25 may be formed by one or more epitaxy or epitaxial (epi) processes. The epitaxy processes include chemical vapor deposition (CVD) deposition techniques (e.g., vapor-phase epitaxy (VPE) and/or ultra-high vacuum CVD (UHV-CVD)), molecular beam epitaxy, and/or other suitable processes.

The first semiconductor layers 20 and the second semiconductor layers 25 are epitaxially formed over the substrate 10 alternately. The thickness of the first semiconductor layers 20 may be equal to or greater than that of the second semiconductor layers 25, and is in a range from about 3 nm to about 30 nm in some embodiments, and is in a range from about 4 nm to about 15 nm in other embodiments. The thickness of the second semiconductor layers 25 is in a range from about 3 nm to about 30 nm in some embodiments, and is in a range from about 4 nm to about 15 nm in other embodiments. The thickness of the first semiconductor layers 20 may be the same as, or different from the thickness of the second semiconductor layers 25. Although three first semiconductor layers 20 and three second semiconductor layers 25 are shown in FIG. 1, the numbers are not limited to three, and can be one, two, or more than 3, and less than twenty. In some embodiments, the number of the first semiconductor layers 20 is greater by one than the number of the second semiconductor layers 25 (i.e.—the top and bottom layers are the first semiconductor layer).

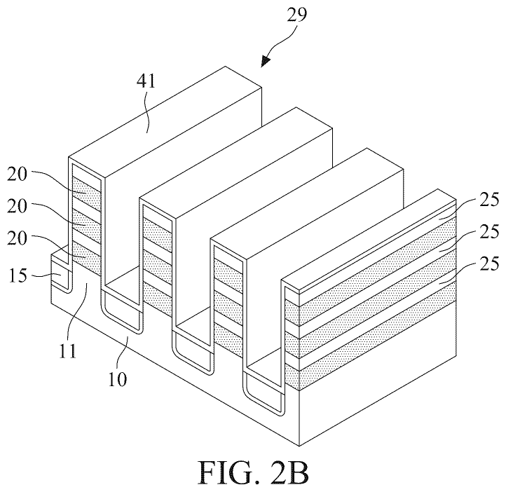

After the stacked semiconductor layers are formed, fin structures 29 are formed by using one or more lithography and etching operations, as shown in FIGS. 2A and 2B. The fin structures may be patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

As shown in FIG. 2A, the fin structures 29 extend in the X direction and are arranged in the Y direction. The number of the fin structures is not limited to two as shown in FIG. 2A, and may be as small as one and three or more (as shown in FIG. 2B). In some embodiments, one or more dummy fin structures are formed on both sides of the fin structures 29 to improve pattern fidelity in the patterning operations. As shown in FIG. 2A, the fin structures 29 have upper portions constituted by the stacked semiconductor layers 20, 25 and well portions 11 (a mesa structure).

The width of the upper portion of the fin structure 29 along the Y direction is in a range from about 5 nm to about 80 nm in some embodiments, and is in a range from about 10 nm to about 40 nm in other embodiments.

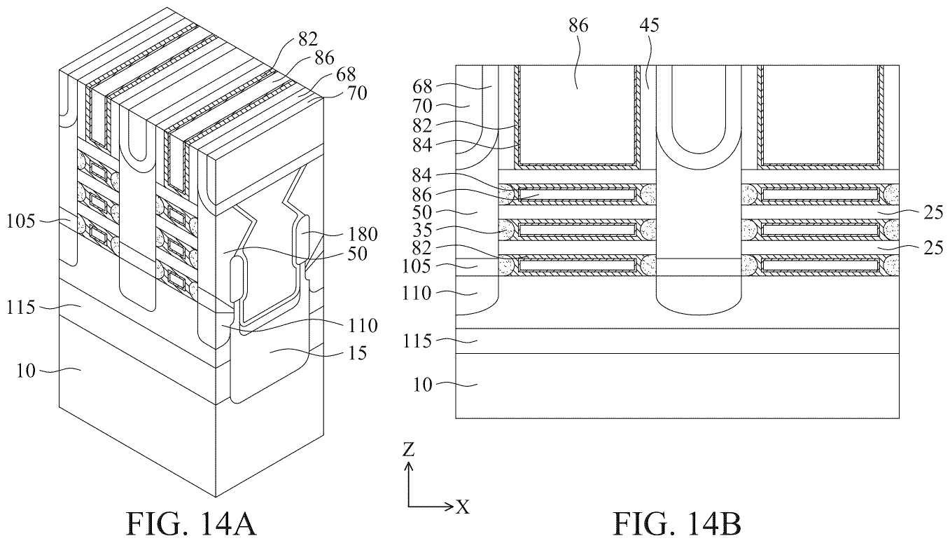

After the fin structures 29 are formed, an insulating material layer including one or more layers of insulating material is formed over the substrate so that the fin structures are fully embedded in the insulating layer. The insulating material for the insulating layer may include silicon oxide, silicon nitride, silicon oxynitride (SiON), SiOCN, SiCN, fluorine-doped silicate glass (FSG), or a low-k dielectric material, formed by LPCVD (low pressure chemical vapor deposition), plasma-enhanced CVD (PECVD), or flowable CVD. An anneal operation may be performed after the formation of the insulating layer. Then, a planarization operation, such as a chemical mechanical polishing (CMP) method and/or an etch-back method, is performed such that the upper surface of the uppermost second semiconductor layer 25 is exposed from the insulating material layer. In some embodiments, one or more fin liner layers 180 (see e.g., FIGS. 14A, 15A, 16A, 17A, 17B, 18A, and 18B) are formed over the fin structures before forming the insulating material layer. In some embodiments, the fin liner layers 180 include a first fin liner layer formed over the substrate 10 and sidewalls of the bottom part of the fin structures 11, and a second fin liner layer formed on the first fin liner layer. The fin liner layers are made of silicon nitride or a silicon nitride-based material (e.g., SiON, SiCN or SiOCN), in some embodiments. The fin liner layers may be deposited through one or more processes such as physical vapor deposition (PVD), chemical vapor deposition (CVD), or atomic layer deposition (ALD), although any acceptable process may be utilized.

Then, as shown in FIG. 2A, the insulating material layer is recessed to form an isolation insulating layer 15 so that the upper portions of the fin structures 29 are exposed. With this operation, the fin structures 29 are separated from each other by the isolation insulating layer 15, which is also called a shallow trench isolation (STI). The isolation insulating layer 15 may be made of suitable dielectric materials, such as silicon oxide, silicon nitride, silicon oxynitride, fluorine-doped silicate glass (FSG); low-k dielectrics, such as carbon doped oxides; extreme low-k dielectrics, such as porous carbon doped silicon dioxide; a polymer, such as polyimide; combinations of these, or the like. In some embodiments, the isolation insulating layer 15 is formed through a process such as CVD, flowable CVD (FCVD), or a spin-on-glass process, although any acceptable process may be used.

In some embodiments, the insulating material layer 15 is recessed until the upper portion of the fin structure (well layer) 11 is exposed. In other embodiments, the upper portion of the fin structure 11 is not exposed. The first semiconductor layers 20 are sacrificial layers which are subsequently partially removed, and the second semiconductor layers 25 are subsequently formed into semiconductor wires, nanostructures, or nanosheets as channel layers of a GAA FET. In other embodiments, the second semiconductor layers 25 are sacrificial layers which are subsequently partially removed, and the first semiconductor layers 20 are subsequently formed into semiconductor wires, nanostructures, or nanosheets as channel layers.

FIG. 2B is an isometric view showing a plurality of fin structures 29 separated by shallow trench isolations 15 after a sacrificial gate dielectric layer 41 is formed over the fin structures 29 and over the shallow trench isolation 15.

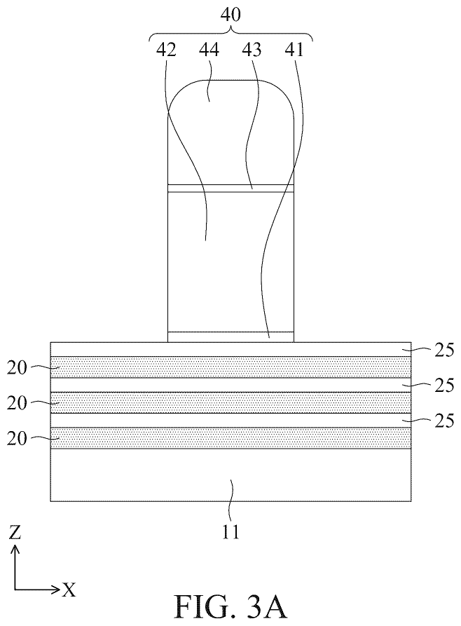

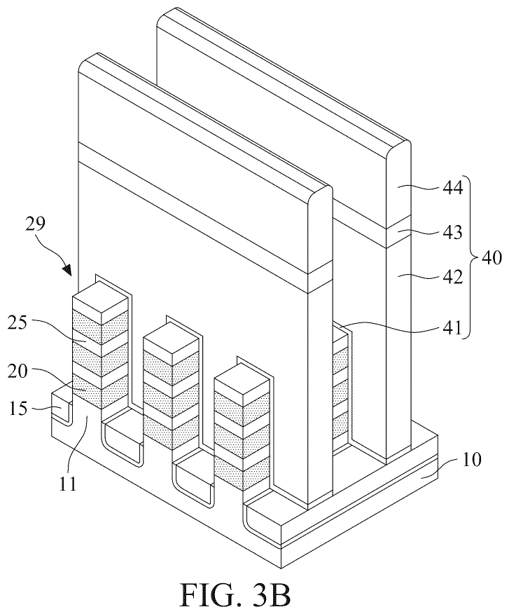

After the isolation insulating layer 15 is formed, one or more sacrificial (dummy) gate structures 40 are formed. FIGS. 3A and 3B illustrate a structure after one or more sacrificial gate structures 40 are formed over the exposed fin structures 29. FIG. 3B is an isometric view of the structure. The sacrificial gate structures 40 are formed over a portion of the fin structures 29 which is to be a channel region. The sacrificial gate structures 40 define the channel regions of the GAA FET. The sacrificial gate structures 40 include a sacrificial gate dielectric layer 41 and a sacrificial gate electrode layer 42. The sacrificial gate dielectric layer 41 includes one or more layers of insulating material, such as a silicon oxide-based material. In one embodiment, silicon oxide formed by CVD is used. The thickness of the sacrificial gate dielectric layer 41 is in a range from about 1 nm to about 5 nm in some embodiments.

The sacrificial gate structures 40 are formed by first blanket depositing the sacrificial gate dielectric layer 41 over the fin structures 29. A sacrificial gate electrode layer 42 is then blanket deposited on the sacrificial gate dielectric layer and over the fin structures, such that the fin structures are fully embedded in the sacrificial gate electrode layer. In some embodiments, the sacrificial gate electrode layer 42 includes silicon such as polycrystalline silicon or amorphous silicon. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. Subsequently, a mask layer is formed over the sacrificial gate electrode layer. In some embodiments, the mask layer includes a pad silicon nitride layer 43 and a silicon oxide mask layer 44.

Next, a patterning operation is performed on the mask layer and sacrificial gate electrode layer is patterned into the sacrificial gate structure 40, as shown in FIGS. 3A and 3B. In an embodiment, the sacrificial gate structure includes the sacrificial gate dielectric layer 41, the sacrificial gate electrode layer 42 (e.g., polysilicon), the pad silicon nitride layer 43 and the silicon oxide mask layer 44. By patterning the sacrificial gate structure, the stacked layers of the first and second semiconductor layers are partially exposed on opposite sides of the sacrificial gate structure, thereby defining source/drain regions, as shown in FIGS. 3A and 3B. In some embodiments, one sacrificial gate structure is formed over one or more fin structures, but the number of the sacrificial gate structures per fin structure is not limited to one. Two or more sacrificial gate structures are arranged in the X direction in some embodiments. In certain embodiments, one or more dummy sacrificial gate structures are formed on both sides of the sacrificial gate structures to improve pattern fidelity.

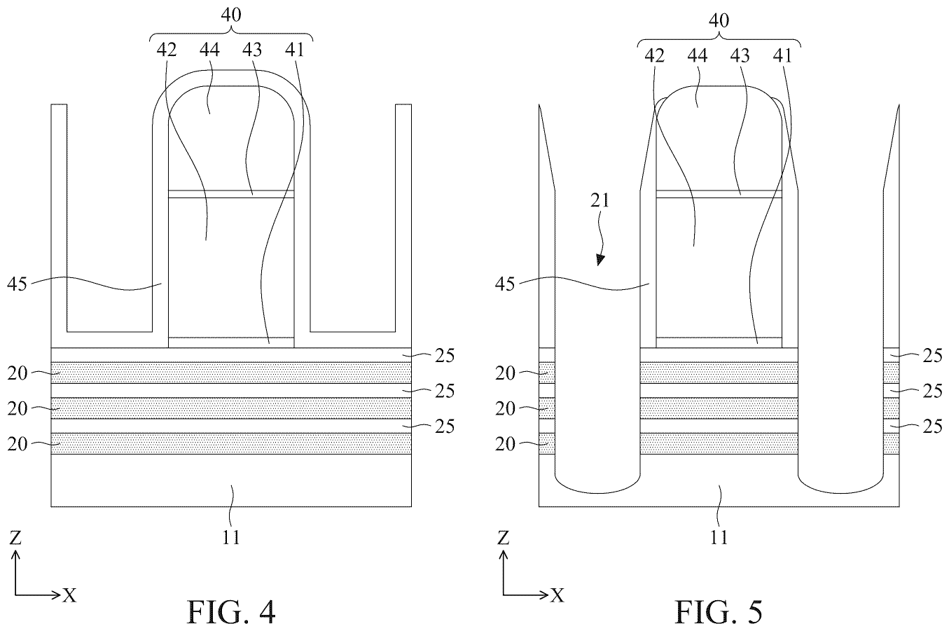

After the sacrificial gate structure 40 is formed, a first cover layer 45 for gate sidewall spacers is formed over the sacrificial gate structure 40, as shown in FIG. 4. The first cover layer 45 is deposited in a conformal manner so that it is formed to have substantially equal thicknesses on vertical surfaces, such as the sidewalls, horizontal surfaces, and the top of the sacrificial gate structure, respectively. In some embodiments, the first cover layer 45 has a thickness in a range from about 5 nm to about 20 nm. The first cover layer 45 includes one or more of silicon nitride, silicon oxide, SiON, SiCN, SiCO, SiOCN or any other suitable dielectric material. The cover layer 45 can be formed by ALD or CVD, or any other suitable method. In some embodiments, one or more additional cover layers are formed over the first cover layer to form multi-layer gate sidewall spacers.

Next, as shown in FIG. 5, the first cover layer 45 is anisotropically etched to remove the first cover layer 45 disposed on the source/drain region, while leaving the first cover layer 45 as sidewall spacers on side faces of the sacrificial gate structure 40. FIG. 5 shows a cross sectional view along the X direction. Then the stacked structure of the first semiconductor layers 20 and the second semiconductor layer 25 is etched down at the source/drain region, by using one or more lithography and etching operations, thereby forming a source/drain space 21. In some embodiments, the substrate 10 (or the bottom part of the fin structures 11) is also partially etched to form a mesa structure. In some embodiments, an n-type FET and a p-type FET are manufactured separately, and in such a case, a region for one type of FET is processed, and a region for the other type of FET is covered by a protective layer, such as a silicon nitride layer. In some embodiments, as shown in FIG. 5, the recessed fin structure has a U-shape. In other embodiments, the recessed fin structure has a V-shape showing (111) facets of a silicon crystal. In other embodiments, the recess has a reverse trapezoid shape, or a rectangular shape.

In some embodiments, the recess is formed by a dry etching process, which may be anisotropic. The anisotropic etching process may be performed using a process gas mixture including BF₂, Cl₂, CH₃F, CH₄, HBr, O₂, Ar, and other etchant gases. Process gases may be activated into a plasma by any suitable method of generating the plasma, such as transformer coupled plasma (TCP) systems, inductively coupled plasma (ICP) systems, magnetically enhanced reactive ion techniques. The plasma is a remote plasma that is generated in a separate plasma generation chamber connected to the processing chamber in some embodiments. The process gases used in the plasma etching process includes etchant gases such as H₂, Ar, other gases, or a combination of gases. In some embodiments, carrier gases, such as N₂, Ar, He, Xe, are combined with a plasma etching process gas using hydrogen (H) radicals. The H radicals may be formed by flowing H₂ gas into a plasma generation chamber and igniting a plasma within the plasma generation chamber. In some embodiments, an additional gas may be ignited into a plasma within the plasma generation chamber, such as Ar. The H radicals may selectively etch (100) planes over (111) planes or (110) planes. In some cases, the etch rate of the (100) planes is about three times greater than the etch rate of (111) planes. Due to this selectivity, the etching by the H radicals may tend to slow or stop along (111) planes or (110) planes of silicon during the second patterning process.

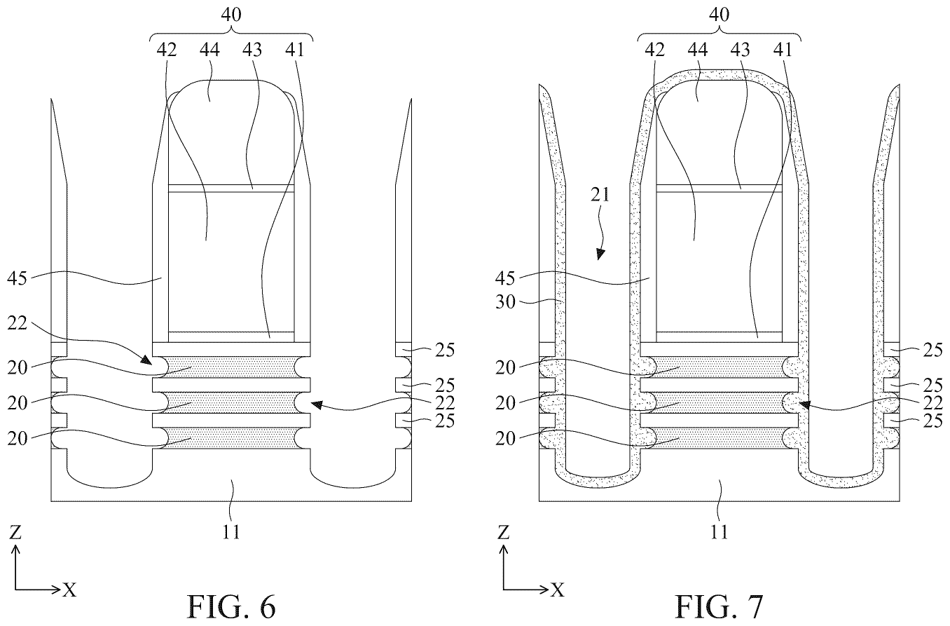

Further, as shown in FIG. 6, the first semiconductor layers 20 are laterally etched in the X direction within the source/drain space 21, thereby forming cavities 22. When the first semiconductor layers 20 are SiGe and the second semiconductor layers 25 are Si, the first semiconductor layers 20 can be selectively etched by using a wet etchant such as, but not limited to, a mixed solution of H₂O₂, CH₃COOH and HF, followed by H₂O cleaning. In some embodiments, the etching by the mixed solution and cleaning by water is repeated 10 to 20 times. The etching time by the mixed solution is in a range from about 1 min to about 2 min in some embodiments. The mixed solution is used at a temperature in a range from about 60 °C to about 90 °C in some embodiments. In some embodiments, other etchants are used.

In some embodiments, the cavity 22 has a curved end shape convex toward the first semiconductor layer 20 (lateral U-shape cross section). In other embodiments, the cavity 22 has a lateral V-shape cross section having an apex at the first semiconductor layer 20.

Next, as shown in FIG. 7, a first insulating layer 30 is formed on the etched lateral ends of the first semiconductor layers 20 and on end faces of the second semiconductor layers 25 in the source/drain space 21 and over the sacrificial gate structure 40. The first insulating layer 30 is conformally formed so that a space is left in the source/drain space 21. The first insulating layer 30 includes one of silicon nitride, including SiN and Si₃N₄, silicon oxide, including SiO and SiO₂, SiON, SiOC, SiCN, and SiOCN, or any other suitable dielectric material. The first insulating layer 30 is made of a different material than the sidewall spacers (first cover layer) 45 in some embodiments, and is made of the same material as the sidewall spacers 45 in other embodiments. The first insulating layer 30 can be formed by ALD or any other suitable methods. By forming the first insulating layer 30, the cavities 22 are fully filled with the first insulating layer 30.

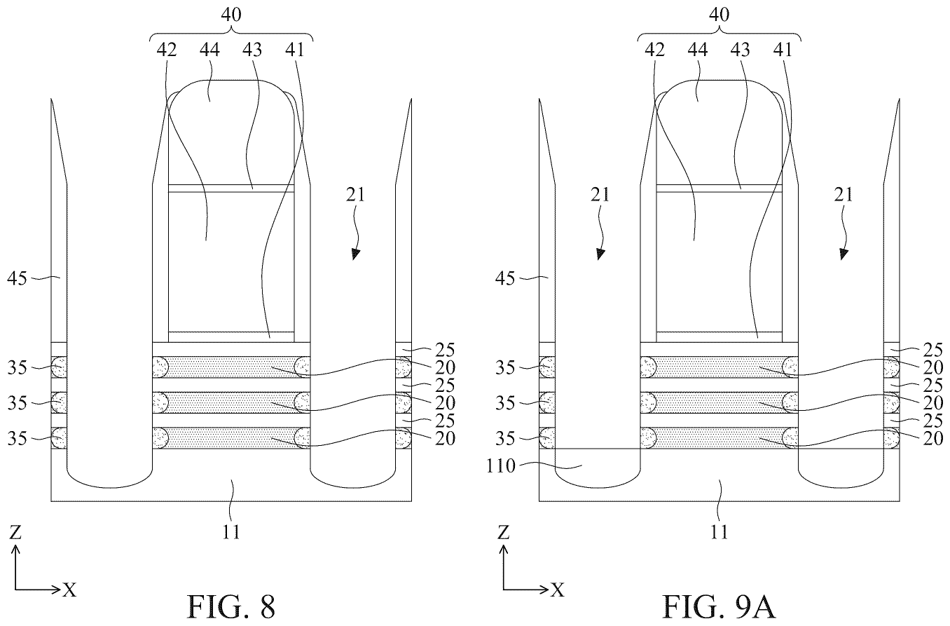

After the first insulating layer 30 is formed, an etching operation is performed to partially remove the first insulating layer 30, thereby forming inner spacers 35, as shown in FIG. 8. In some embodiments, the end face of the inner spacers 35 is recessed more than the end face of the second semiconductor layers 25. The recessed amount is in a range from about 0.2 nm to about 3 nm and is in a range from about 0.5 nm to about 2 nm in other embodiments. In other embodiments, the recessed amount is less than 0.5 nm and may be equal to zero (i.e.—the end face of the inner spacer 35 and the end face of the second semiconductor layers 25 are flush with each other). In some embodiments, before forming the first insulating layer 30, an additional insulating layer having a smaller thickness than the first insulating layer 30 is formed, and thus the inner spacers 35 have a two-layer structure. In some embodiments, widths (lateral length) of the inner spacers 35 are not constant.

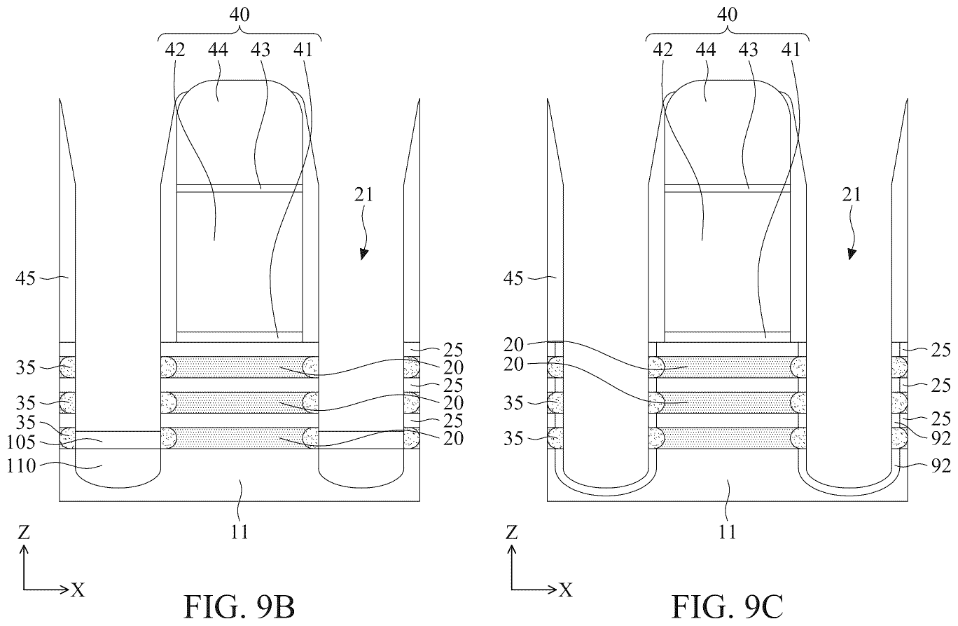

In some embodiments, a bottom semiconductor layer 110 is formed in the bottom of source/drain space 21, as shown in FIG. 9A. The bottom semiconductor layer 110 is an epitaxial layer in some embodiments. In some embodiments, the bottom semiconductor layer is made of SiGeB, SiP, SiAs, SiGe, or Si. The bottom semiconductor layer 110 may be doped or undoped.

A bottom isolation layer or flexible bottom isolation layer 105 is formed over the bottom semiconductor layer in some embodiments, as shown in FIG. 9B. In some embodiments, the bottom isolation layer 105 is made of SiC, LaO, an aluminum oxide, including Al₂O₃, an aluminum oxynitride (AlON), ZrO₂, HfO₂, a silicon nitride, including Si₃N₄ and SiN, Si, ZnO, ZrN, ZrAlO, a titanium oxide, including TiO₂, tantalum oxide, including Ta₂O₅ and TaO, Zr, a yttrium oxide, including Y₂O₃, TaCN, zirconium silicide, including ZrSi₂ and ZrSi, SiOCN, SiOC, SiCN, hafnium silicide, including HfSi and HfSi₂, and a silicon oxide, including SiO₂ and SiO. The bottom isolation layer 105 may be formed by a chemical vapor deposition or physical vapor deposition operation. In some embodiments, the bottom isolation layer 105 is formed by oxidizing the surface of the bottom semiconductor layer 110.

In other embodiments, after the inner spacers 35 are formed, a first epitaxial layer 92 is formed on lateral end faces of the second semiconductor layer 25 and the exposed surface of the lower fin structure 11 in some embodiments, as shown in FIG. 9C. In some embodiments, the first epitaxial layer 92 includes Si doped with P or As for an n-type FET and doped with B for a p-type FET. In some embodiments, the dopant concentration of the first epitaxial layer 92 is higher than the dopant concentration of the second semiconductor layers 25. In some embodiments, the dopant concentration of the first epitaxial layer 92 gradually increases from the interface between the first epitaxial layer 92 and the second semiconductor layers 25 or lower fin structure 11 to the source/drain space 21. In some embodiments, the thickness of the first epitaxial layer 92 as deposited is in a range from about 1 nm to about 10 nm. In some embodiments, during the epitaxial formation of the first epitaxial layer 92, some of the dopant elements diffuse into the second semiconductor layer 25 or lower fin structure 11 to a depth of about 0.5 nm to about 2 nm.

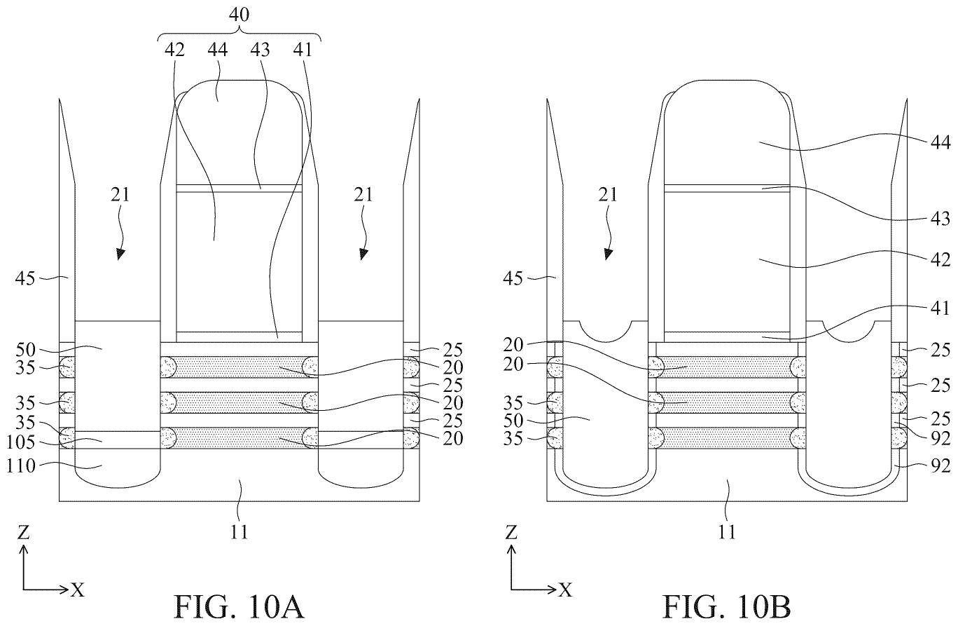

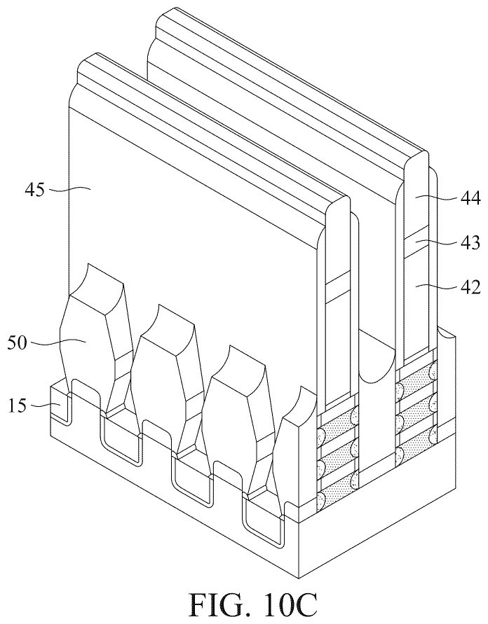

Then, as shown in FIGS. 10A-10C and source/drain structures 50 are formed in the source/drain space 21. FIG. 10A is a cross section view along the X direction showing the source/drain structures being formed in the source/drain space 21 of the structure of FIG. 9B, and FIG. 10B is a cross section view along the X direction showing the source/drain structures being formed in the source/drain space of the structure of FIG. 9C. FIG. 10C is an isometric view of the structure of FIG. 10A. In some embodiments, source/drain structures 50 include one or more layers of SiC, SiP, SiAs, and/or SiCP for an n-type FET. In certain embodiments, SiC or SiCP is used. In some embodiments, the source/drain structure 50 includes SiGe, SiGeSn, Ge, GeSn, and/or SiSn for a p-type FET. When SiGe is used, the Ge content is about 60 atomic % to about 80 atomic % in some embodiments. In some embodiments, the source/drain structures 50 are formed by an epitaxial process. In some embodiments, the source/drain structure 50 applies a tensile stress to the second semiconductor layer 25 for an n-type FET and a compressive stress to a p-type FET.

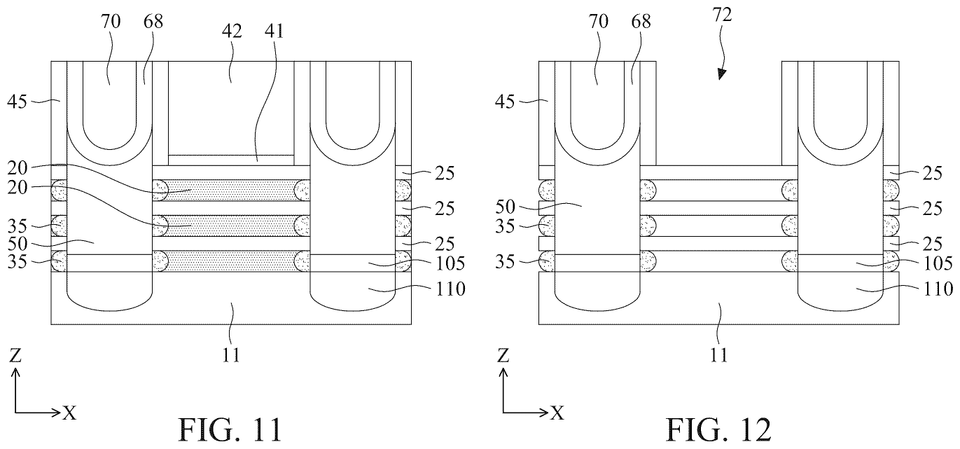

Then, an interlayer dielectric (ILD) layer 70 is formed over the source/drain structure 50 and the sacrificial gate structure 40. In some embodiments, before the ILD layer 70 is formed, a contact etch stop layer 68 is formed. Next, the dielectric layer 70 is planarized by chemical mechanical polishing (CMP) to expose the sacrificial gate electrode layer 42, as shown in FIG. 11. The materials for the ILD layer 70 can include compounds comprising Si, O, C, and/or H, such as a silicon oxide, SiCOH and SiOC. Organic materials, such as a polymer, including polyimide, may be used for the ILD layer 70. Materials for the contact etch stop layer 68 can include a silicon nitride, a silicon oxide, SiCN, SiON, and SiOCN. In some embodiments, the materials for the ILD layer 70 and the etch stop layer 68 are different from each other, and thus have different etch selectivities.

Then, as shown in FIG. 12, the sacrificial gate electrode layer 42 and the sacrificial gate dielectric layer 41 are removed forming a gate space 72. The ILD layer 70 protects the source/drain structures 50 during the removal of the sacrificial gate structures. The sacrificial gate structures can be removed using plasma dry etching and/or wet etching. When the sacrificial gate electrode layer 42 is polysilicon and the dielectric layer 70 is silicon oxide, a wet etchant such as a TMAH solution can be used to selectively remove the sacrificial gate electrode layer 42. The sacrificial gate dielectric layer 41 can thereafter be removed using plasma dry etching and/or wet etching.

After the sacrificial gate structures are removed, the first semiconductor layers 20 are removed, thereby forming nanosheets, nanowires, or nanostructures (channel regions) of the second semiconductor layers 25 stacked along the Z-direction, as shown in FIG. 12. The first semiconductor layers 20 can be removed or etched using an etchant that can selectively etch the first semiconductor layers 20 against the second semiconductor layers 25, as set forth above. Since the inner spacers 35 were previously formed, the etching of the first semiconductor layers 20 stops at the inner spacers 35. In other words, the inner spacers 35 may function as an etch-stop layer for etching of the first semiconductor layers 20.

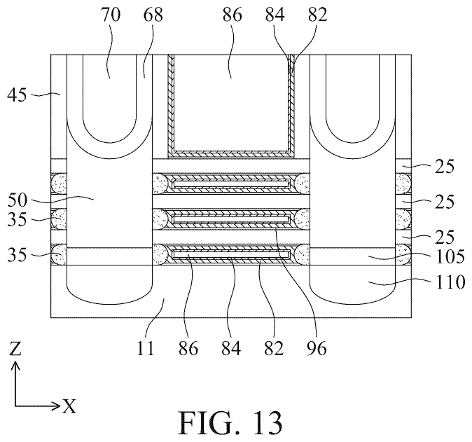

After the semiconductor nanowires or nanosheets (channel regions) of the second semiconductor layers 25 are formed, a metal gate structure is formed as shown in FIG. 13. FIG. 13 is a cross section view along the X direction. In some embodiments, the structure and/or material of the gate electrode for the n-type GAA FET are different from the structure and/or material of the gate electrode for the p-type GAA FET.

In certain embodiments, the gate dielectric layer 82 includes one or more layers of a dielectric material, such as silicon oxide, silicon nitride, or high-k dielectric material, other suitable dielectric material, and/or combinations thereof. High-k dielectric materials have a dielectric constant greater than that of silicon dioxide or greater than about 3.9. Examples of high-k dielectric material include HfO₂, HfSiO, HfSiON, HfTaO, HfTiO, HfZrO, zirconium oxide, aluminum oxide, titanium oxide, lanthanum oxide, hafnium dioxide-alumina (HfO2—Al₂O3) alloy, other suitable high-k dielectric materials, and/or combinations thereof. In some embodiments, the gate dielectric layer 82 includes an interfacial layer 96 formed between the channel layers and the dielectric material.

The gate dielectric layer 82 may be formed by CVD, ALD, or any suitable method. In one embodiment, the gate dielectric layer is formed using a highly conformal deposition process such as ALD in order to ensure the formation of a gate dielectric layer having a uniform thickness around each channel layer. The thickness of the gate dielectric layer 82 is in a range from about 1 nm to about 6 nm in one embodiment.

In some embodiments, the metal gate structure includes one or more work function adjustment layers 84 disposed over the gate dielectric layer 82. The work function adjustment layers 84 are made of a conductive material such as a single layer of TiN, TaN, TaAlC, TiC, TaC, Co, Al, TiAl, HfTi, TiSi, TaSi or TiAlC, or a multilayer of two or more of these materials. In some embodiments, one or more of TiAlC, Al, TiAl, TaN, TaAlC, TiN, TiC and Co are used as the work function adjustment layer for the p-channel FET. For an n-channel FET, one or more of TaN, TaAlC, TiN, TiC, Co, TiAl, HfTi, TiSi, and TaSi is used as the work function adjustment layer, according to some embodiments. The work function adjustment layer may be formed by ALD, PVD, CVD, e-beam evaporation, or other suitable process. Further, the work function adjustment layer may be formed separately for the n-channel FET and the p-channel FET which may use different metal layers.

The gate electrode layer 86 is formed on the work function adjustment layer 84 if present or on the gate dielectric layer 82 to surround each channel layer. The gate electrode layer 86 includes one or more layers of conductive material, such as polysilicon, aluminum, copper, titanium, tantalum, tungsten, cobalt, molybdenum, ruthenium, tantalum nitride, nickel silicide, cobalt silicide, TiN, WN, TiAl, TiAlN, TaCN, TaC, TaSiN, metal alloys, other suitable materials, and/or combinations thereof.

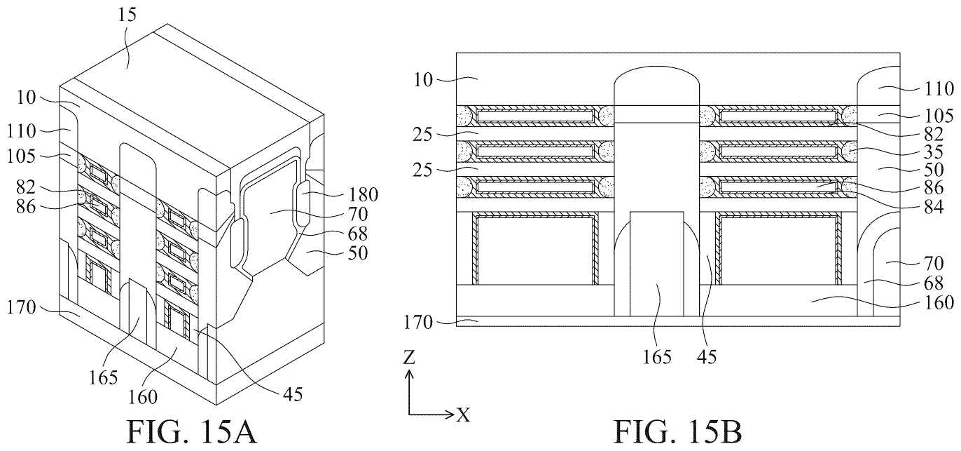

The gate electrode layer 86 may be formed by CVD, ALD, electro-plating, or other suitable method. The gate electrode layer is also deposited over the upper surface of the ILD layer 70. The gate dielectric layer, work function adjustment layer, and the gate electrode layer formed over the ILD layer 70 are then planarized by using, for example, CMP, until the top surface of the ILD layer 70 is revealed. In some embodiments, after the planarization operation, the gate electrode is recessed and a cap insulating layer 160 (see FIGS. 15A and 15B) is formed over the recessed gate electrode. In some embodiments, the cap insulating layer includes one or more layers of a silicon nitride-based material, such as silicon nitride. The cap insulating layer is formed by depositing an insulating material followed by a planarization operation.

FIGS. 14A to 31B are schematic illustrations showing various stages of forming a backside via contact in a semiconductor FET device according to embodiments of the present disclosure. It is understood that additional operations can be provided before, during, and after processes shown by FIGS. 14A-31B, and some of the operations described below can be replaced or eliminated, for additional embodiments of the method. The order of the operations/processes may be interchangeable. It is understood that some features of some embodiments may not be shown in each figure to simplify the figures, and to better illustrate other features of the disclosed embodiments.

FIG. 14A and FIG. 14B respectively show an isometric view and a cross sectional view of one of the various stages of manufacturing a GAA FET semiconductor device according to an embodiment of the present disclosure. In some embodiments, an etch stop layer 115 is formed in the substrate 10, as shown in FIG. 14A, before the FET structures are formed. The etch stop layer 115 may be made of a semiconductor having a different etch selectivity than the substrate 10. For example, if the substrate 10 is a silicon substrate the etch stop layer 115 may be made of SiGe.

While 3 nanosheets 25 are shown in each transistor, the number of nanosheets in each transistor ranges from 2 to about 20 in some embodiments, and from about 2 to about 10 in other embodiments. By adjusting the number of the semiconductor nanostructures (nanowires, nanosheets . . . etc.), a driving current of the GAA FET device can be adjusted.

FIG. 15A and FIG. 15B respectively show an isometric view and a cross sectional view of one of the various stages of manufacturing a GAA FET semiconductor device according to an embodiment of the present disclosure. In some embodiments, a gate cap insulating layer 160 is formed over the gate structure and a front side conductive contact 165 is formed over the source/drain region 50. The front side conductive contact 165 is electrically connected to the source/drain region 50. The gate cap insulating layer 160 is made of a dielectric layer, such as silicon oxide or silicon nitride in some embodiments. In some embodiments, the front side conductive contact 165 is formed by lithography, etching, and material deposition techniques. In some embodiments, the front side contact 165 is made of W, Ru, Co, Cu, Mo, or combinations thereof. In some embodiments, a glue layer made of TaN or TiN is formed over the source/drain region 50 before the front side contact material is deposited. In some embodiments, a planarizing layer 170 is formed over the gate cap insulating layer 160 and the front side conductive contact 165, as shown in FIGS. 15A and 15B. The planarizing layer 170 may be an insulating layer in some embodiments, such as an oxide or nitride.

As shown in FIGS. 15A and 15B, the backside of the semiconductor device structure is thinned. The backside may be thinned by an etching operation or by chemical-mechanical polishing (CMP). In some embodiments, the backside is thinned down to the etch stop layer 115, and then the etch stop layer 115 is removed by a suitable etching technique to reveal the isolation insulating layer 15. As shown in FIGS. 15A and 15B, the semiconductor device structure is flipped over so that the backside is at the top of the structure.

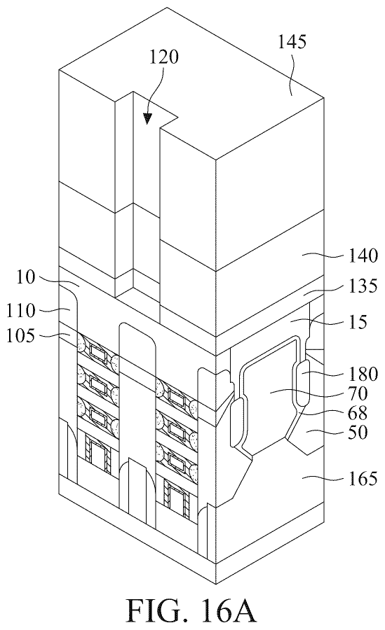

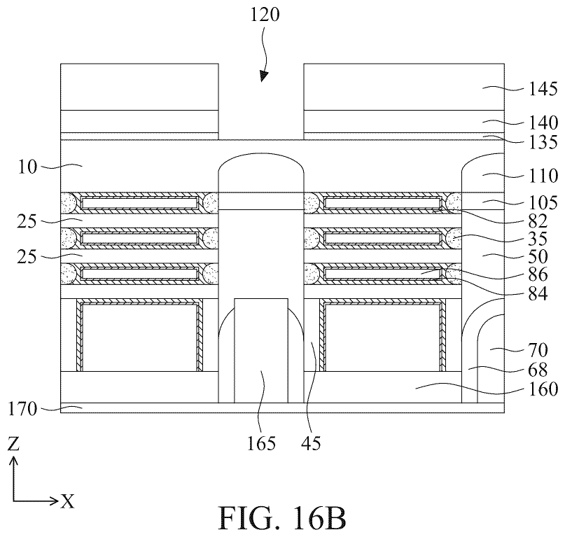

FIG. 16A and FIG. 16B respectively show an isometric view and a cross sectional view of one of the various stages of manufacturing a GAA FET semiconductor device according to an embodiment of the present disclosure. A hard mask layer 135, 140 is formed over the backside of the semiconductor device structure. In some embodiments, the hard mask layer includes a silicon oxide layer 140 formed over a silicon nitride layer 135, as shown in FIGS. 16A and 16B, using suitable deposition techniques. Then, a photoresist layer 145 is formed over the hard mask layer 135, 140. In some embodiments, the photoresist layer is a trilayer resist including an organic bottom layer, a silicon-containing middle layer, and a photosensitive upper layer. The photoresist layer 145 is patterned using suitable photolithographic techniques forming an opening 120 in the photoresist layer, and the opening 120 is extended through the hard mask layer 135, 140 using suitable etching techniques and etchants to expose a portion of the substrate 10. In some embodiments, the hard mask layer 135, 140 is etched using anisotropic dry etching techniques.

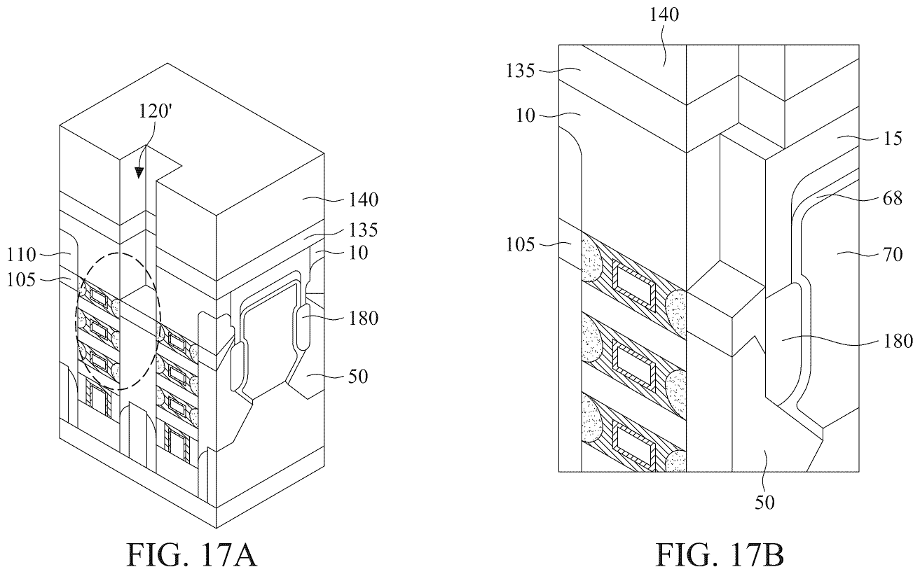

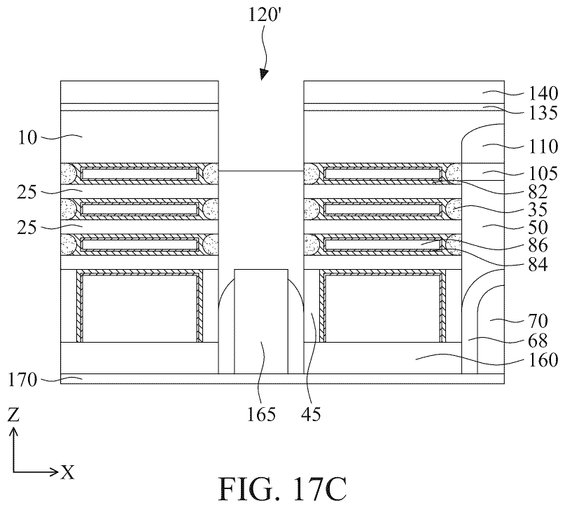

The photoresist layer 145 is removed using a suitable photoresist stripping operation or plasma ashing operation, as shown in FIG. 17A and FIG. 17C, and the opening 120′ is extended into the substrate 10 and through the bottom semiconductor layer 110 forming a trench exposing the bottom isolation layer 105 in some embodiments. FIG. 17A shows an isometric view, FIG. 17B shows a detailed isometric view of the portion of FIG. 17A surrounded by the dashed line, and FIG. 17C shows a cross sectional view according to an embodiment of the present disclosure. Suitable etchants and etching techniques are used depending on the etch selectivity of the layers being etched.

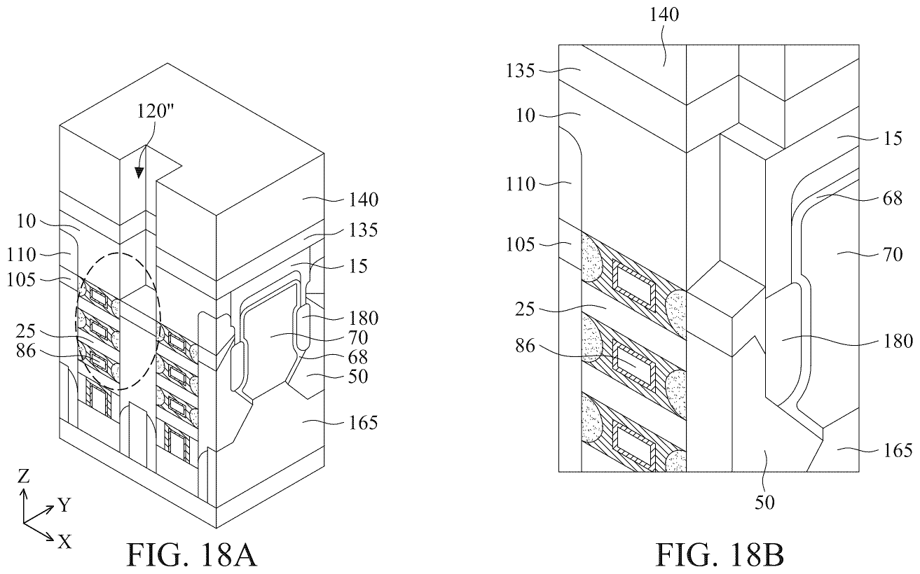

FIG. 18A shows an isometric view of one of the various stages of manufacturing a GAA FET semiconductor device according to an embodiment of the present disclosure. FIG. 18B shows a detailed isometric view of a portion of FIG. 18A surrounded by the dashed line. In FIGS. 18A and 18B, the trench 120″ is enlarged along a direction parallel to the direction that the nanosheets 25 and gate electrode layers 86 extend (the Y-direction). The trench 120″ is enlarged along the Y-direction by first implanting a dopant into the trench sidewalls at a tilt angle along the Y-direction. In some embodiments, the implanted dopant is one or more selected from Ar, La, Al, or Xe. The implant damages the sidewall of the trench making the damaged sidewalls more selective to a subsequently applied wet etchant. Thus, the implant damaged sidewalls are preferentially etched over other surfaces exposed to the wet etchant. In some embodiments, the wet etchant includes one or more selected from SC1 (NH₄OH: H₂O₂: H₂O solution), SC2 (HCl: H₂O₂: H₂O solution), H₂O₂, deionized water and ozone solution, and dilute HF solution. Because the trench is preferentially etched along the Y-direction and the trench is not significantly enlarged along the X-direction (between adjacent gate electrode stacks) gate current leakage is prevented. In some embodiments the dimension of the trench (or the subsequently formed silicide layer) along the Y-direction is larger than along X-direction.

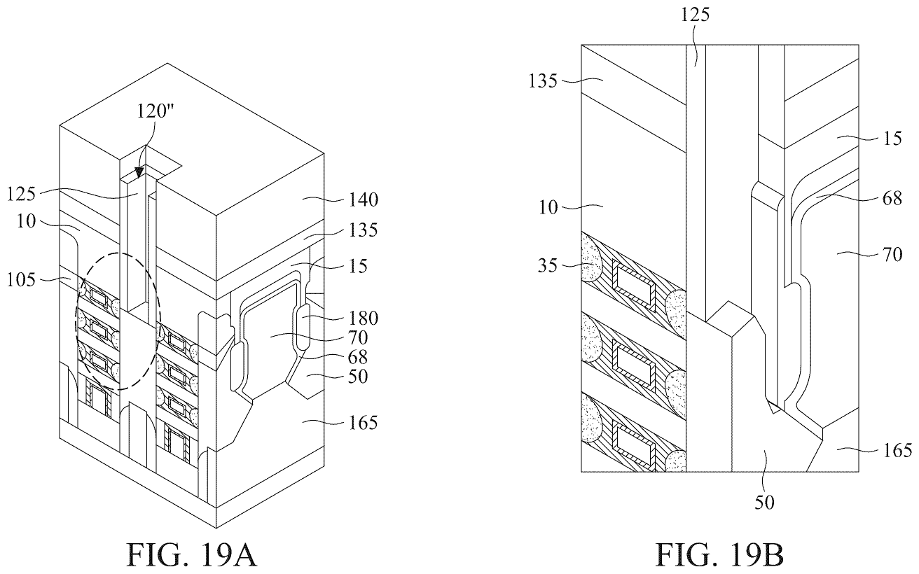

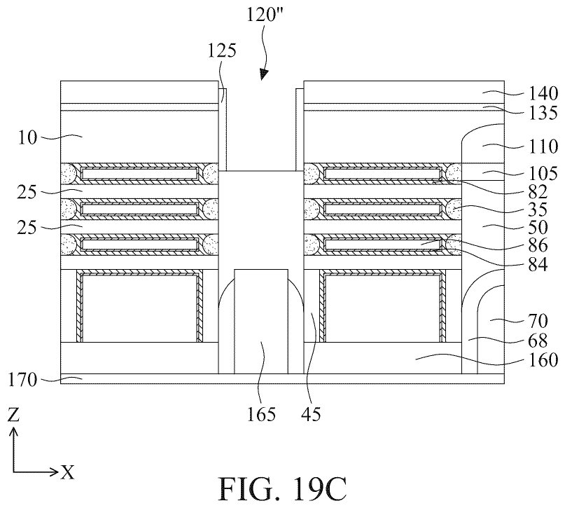

FIG. 19A shows an isometric view of one of the various stages of manufacturing a GAA FET semiconductor device according to an embodiment of the present disclosure. FIG. 19B shows a detailed isometric view of a portion of FIG. 19A surrounded by the dashed line, and FIG. 19C shows a cross sectional view of FIG. 19A. In FIGS. 19A-19C, a barrier layer 125 is conformally formed in the enlarged trench 120″. The barrier layer 125 is an oxide or a nitride layer, such as a silicon oxide, silicon nitride, or a metal nitride in some embodiments. The barrier layer 125 may be formed by any suitable technique, including CVD or ALD. The barrier layer 125 is subsequently anisotropically etched to expose the source/drain region 50. In some embodiments, a portion of the sourec/drain region is etched during the barrier layer etching operation. In some embodiments, the barrier layer 125 is formed, and then the barrier layer 125 and the isolation layer 105 are anisotropically etched to expose the source/drain region. In other embodiments, the isolation layer 105 is etched, then the barrier layer 125 is formed, and the barrier layer is subsequently anisotropically etched to expose the source/drain region.

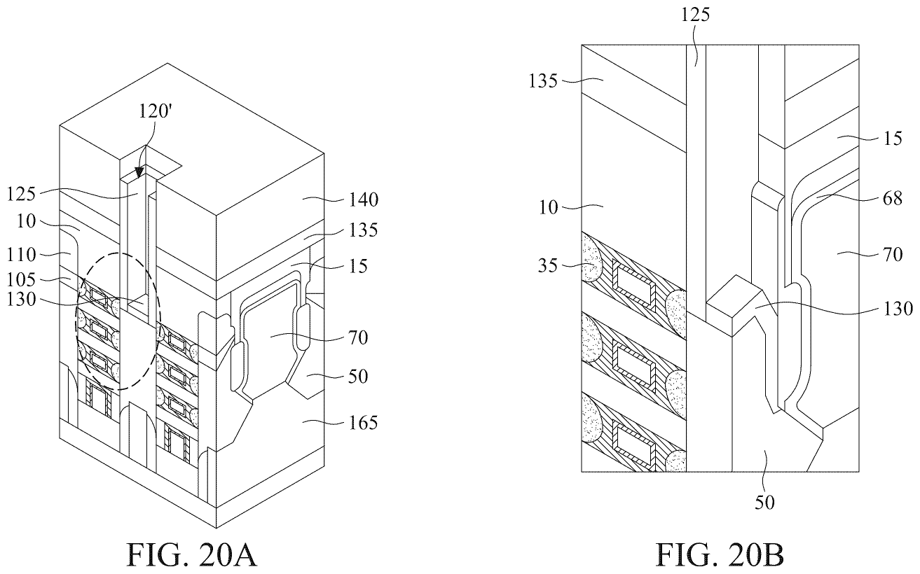

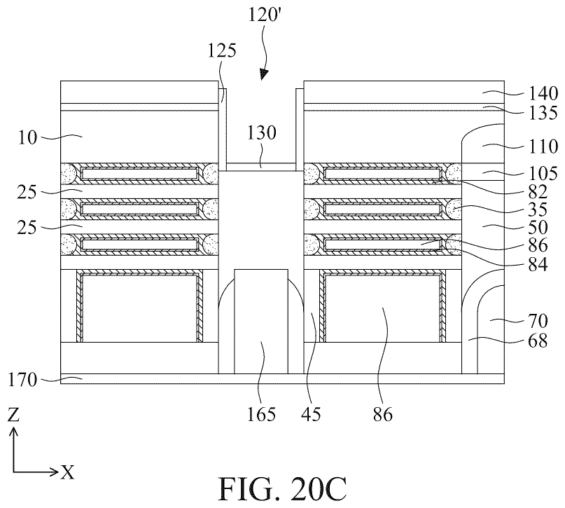

FIG. 20A shows an isometric view of one of the various stages of manufacturing a GAA FET semiconductor device according to an embodiment of the present disclosure. FIG. 20B shows a detailed isometric view of a portion of FIG. 20A surrounded by the dashed line and FIG. 20C shows a cross sectional view of FIG. 20A. A metal silicide layer 130 is formed contacting the source/drain region 50. The metal silicide layer 130 is formed by depositing a metal layer over the source/drain region 50 and then heating the source/drain region 50 and the metal layer to react the metal with silicon in the source/drain region, thereby forming the metal silicide layer 130. The metal layer may include one or more of Ti, Mo, Ru, W, Rh, Nb, Ir, Y, Sb, Sc, Zr, Mo, Ni, and Co. The metal layer may be formed by any suitable technique including physical vapor deposition techniques. In some embodiments, the metal silicide layer 130 includes one or more of TiSi, TiSi₂, MoSi, MoSi₂, YSi, WSi, WSi₂, YSi₂, ZrSi, ZrSi₂, NbSi, NbSi₂, RuₓSi_{y}, where 1≤x≤5 and 1≤y≤5, RhSi, IrSi, SbSi, and ScSi.

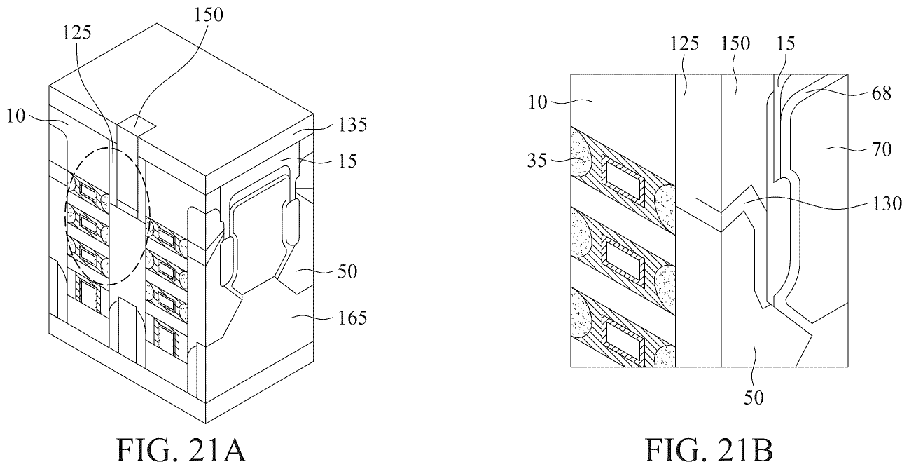

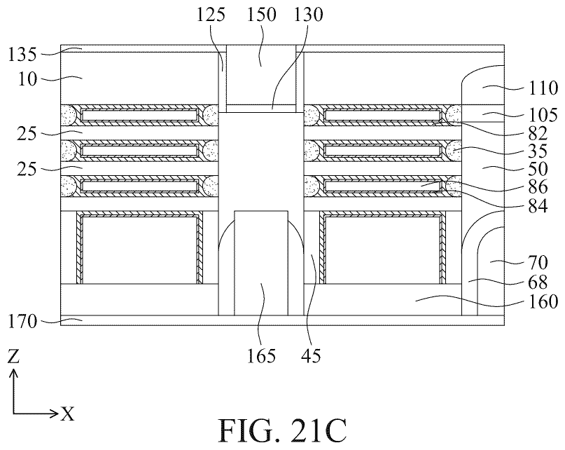

FIG. 21A shows an isometric view of one of the various stages of manufacturing a GAA FET semiconductor device according to an embodiment of the present disclosure. FIG. 21B shows a detailed isometric view of a portion of FIG. 21A surrounded by the dashed line and FIG. 21C shows a cross sectional view. A backside conductive contact 150 is subsequently formed in the enlarged trench 120″. The backside conductive contact 150 is made of one or more of W, Ru, Co, Cu, or Mo in some embodiments. In some embodiments, a glue layer made of TaN or TiN is formed over the silicide layer 130 before the backside contact material is deposited. In some embodiments, the backside contact material is deposited by PVD, CVD, ALD, or plating techniques. Excess backside contact material and the hard mask layer 135, 140 is subsequently removed and the backside is planarized by a CMP operation or an etch back operation in some embodiments. In some embodiments, a planarized portion of the hard mask layer 135 remains after the CMP or etch back operation as shown in FIGS. 21A and 21B.

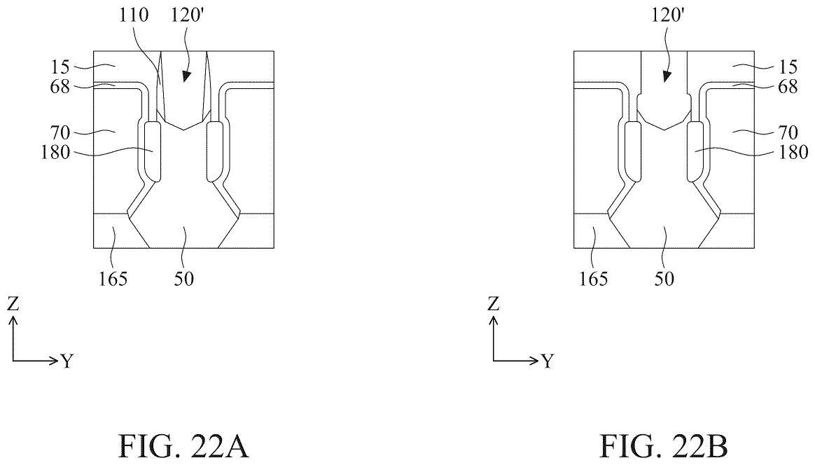

FIGS. 22A and 22B show cross sectional views of various stages of manufacturing a GAA FET semiconductor device along the Y-direction according to embodiments of the present disclosure. FIG. 22A shows a detail of the backside at the source/drain region 50 after the backside via etch. In some embodiments, a portion of the bottom semiconductor layer 110 remains on the sidewall of the opening 120′, as shown in FIG. 22A. In other embodiments, the entire bottom semiconductor layer is removed during the backside via etch, as shown in FIG. 22B. By removing all the bottom semiconductor layer the area of the subsequently formed silicide layer can be increased. In some embodiments, the amount of sidewall etching is controlled by the selection of the etchant, such as anisotropic or isotropic etchants.

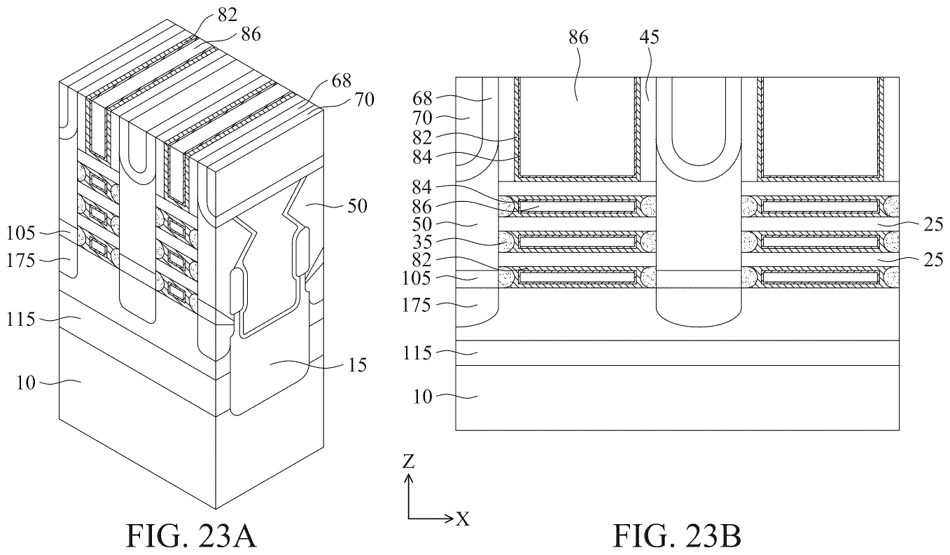

FIG. 23A and FIG. 23B respectively show an isometric view and a cross sectional view of one of the various stages of manufacturing a GAA FET semiconductor device according to an embodiment of the present disclosure. The embodiment of FIGS. 23A and 23B are similar to the embodiment of FIGS. 14A and 14B with the difference that the bottom semiconductor layer 175 is made of SiGe instead of Si.

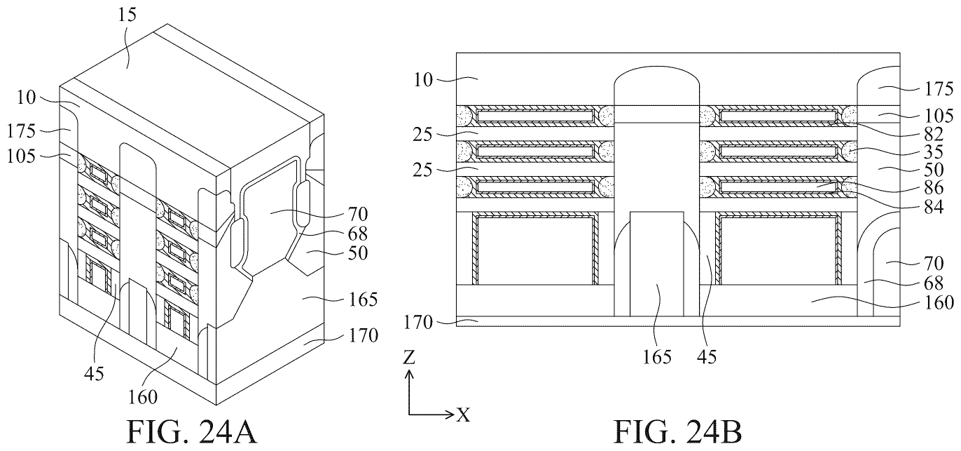

FIG. 24A and FIG. 24B respectively show an isometric view and a cross sectional view of one of the various stages of manufacturing a GAA FET semiconductor device according to an embodiment of the present disclosure. Similar to the embodiment of FIGS. 15A and 15B, a gate cap insulating layer 160 is formed over the gate structure and a front side conductive contact 165 is formed over the source/drain region 50, and the gate cap insulating layer 160 and front side conductive contact 165 are formed in the same manner as in the embodiment of FIGS. 15A and 15B. As shown in FIGS. 24A and 24B, the backside of the semiconductor device structure is thinned in the same manner as the embodiment of FIGS. 15A and 15B.

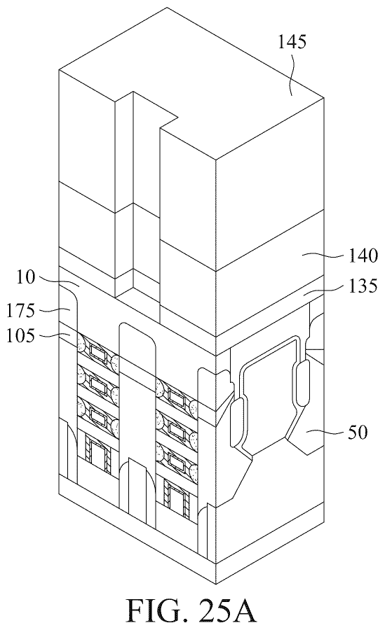

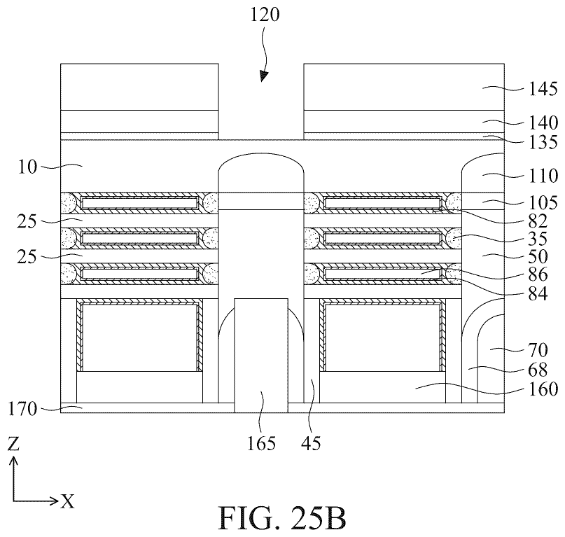

FIG. 25A and FIG. 25B respectively show an isometric view and a cross sectional view of one of the various stages of manufacturing a GAA FET semiconductor device according to an embodiment of the present disclosure. A photoresist layer 145 and hard mask layer 135, 140 are formed and patterned in the same manner as disclosed in the embodiment of FIGS. 16A and 16B.

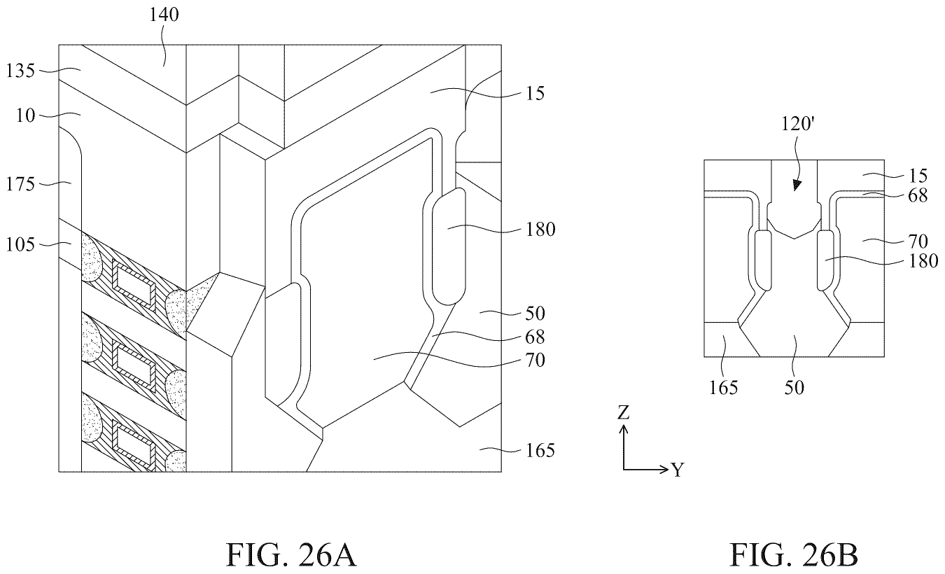

The photoresist layer 145 is subsequently removed and the opening 120′ is extended into the substrate 10 and the SiGe bottom semiconductor layer 175 in a similar manner as described with reference to the embodiment of FIGS. 17A-19C. Depending on the etchant, the SiGe has a higher etch selectivity with respect to the silicon substrate. Thus, the SiGe is completely removed during the backside via etching operation providing a trench 120′ that is self-aligned to the source/drain region 50, as shown in FIGS. 26A and 26B.

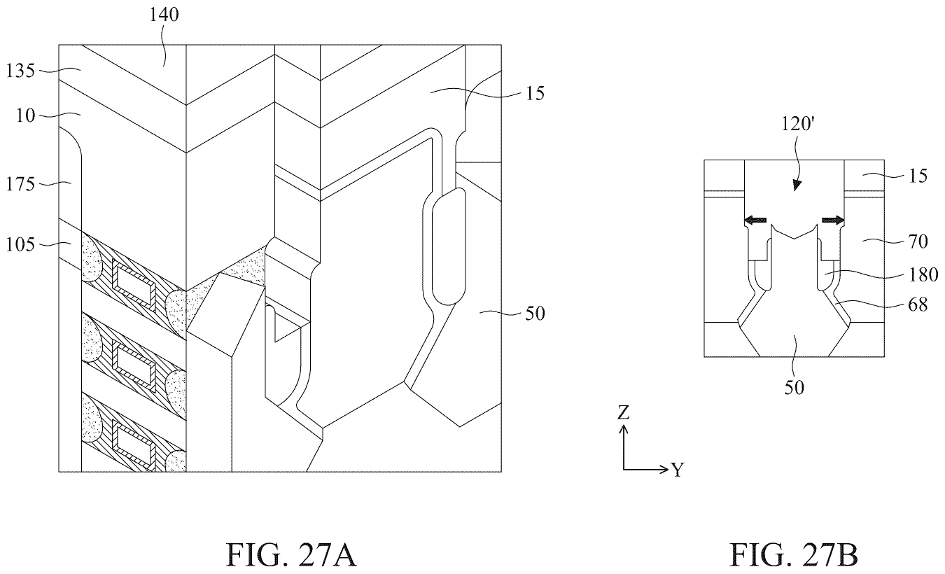

FIG. 27A and FIG. 27B respectively show a detailed isometric view and a detailed cross sectional view of the trench enlargement operation according to embodiments of the present disclosure. As shown, in FIGS. 27A and 27B, the trench 120″ is enlarged along the Y-direction. The trench 120″ is enlarged along the Y-direction by first implanting a dopant into the trench sidewalls at a tilt angle along the Y-direction at a tilt angle ranging from 0 to 90 degrees relative to a vertical line. As disclosed herein with reference to FIGS. 18A and 18B, one or more dopants selected from Ar, La, Al, or Xe are implanted in the sidewalls of the trench making the damaged sidewalls more selective to the subsequently applied wet etchant.

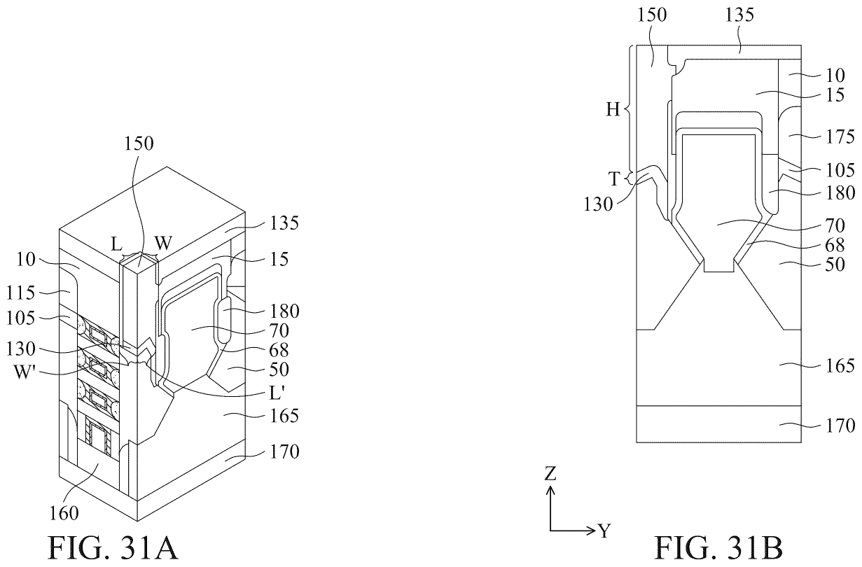

As shown in FIGS. 27A and 27B, the trench 120″ is enlarged along the Y-direction. In some embodiments, the trench 120″ is enlarged by about 1 nm to about 20 nm along the Y-direction. In some embodiments, the trench 120″ is enlarged by about 2 nm to about 15 nm along the Y-direction, and in other embodiments, the trench 120″ is enlarged by about 5 nm to about 10 nm along the Y-direction. In some embodiments, after the trench enlargement, the width W (see FIG. 31A) of the trench 120″ along the X-direction ranges from about 5 nm to about 40 nm and the length L (see FIG. 31A) of the trench 120″ along the Y-direction ranges from about 10 nm to about 80 nm. In some embodiments, a ratio of the length L of the trench 120″ along the Y-direction to the width W of the trench 120″ along the X-direction ranges from about 2:1 to about 16:1, and in other embodiments, the ratio ranges from about 4:1 to about 8:1. In some embodiments, the trench 120″ is also extended by about 1 nm to about 20 nm in the Z-direction, and by about 5 nm to about 10 nm in other embodiments during the trench enlargement operation. As shown in FIGS. 27A and 27B, during the trench enlargement etch, a portion of the interlayer dielectric layer 70, fin liner layer 180, and contact etch stop layer 68 are removed, exposing sidewalls of the source/drain region 50 in some embodiments.

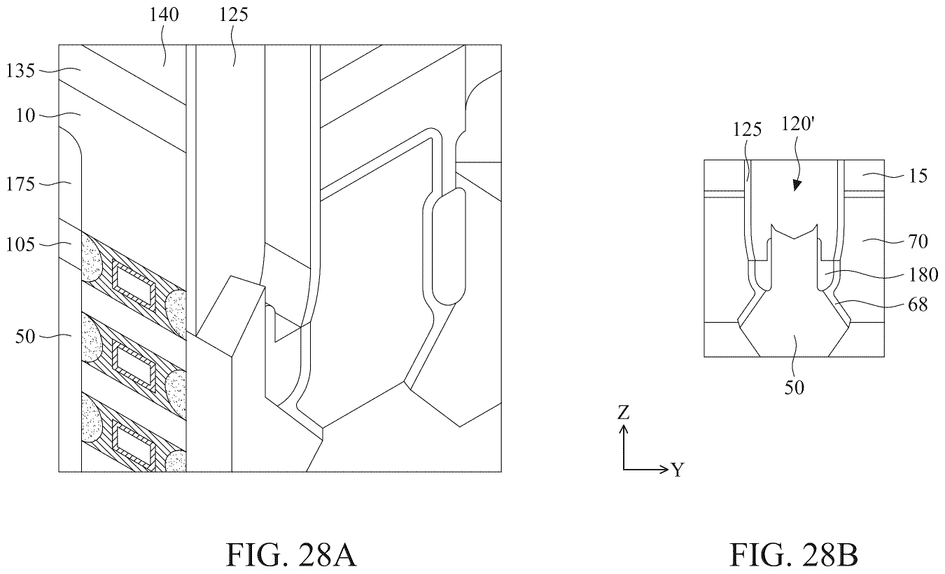

FIG. 28A and FIG. 28B respectively show a detailed isometric view and a detailed cross sectional view of one of the various stages of manufacturing a GAA FET semiconductor device according to an embodiment of the present disclosure. In FIGS. 28A and 28B, a barrier layer 125 is formed over the sidewalls of the enlarged trench 120″ in a similar manner as disclosed herein in reference to FIGS. 19A-19C. The barrier layer 125 is anisotropically etched to expose the source/drain region 50.

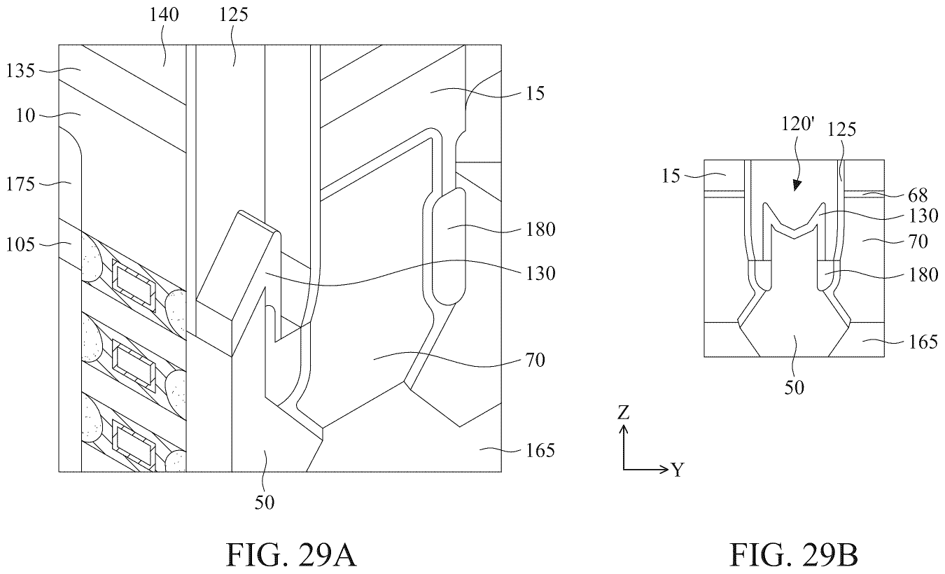

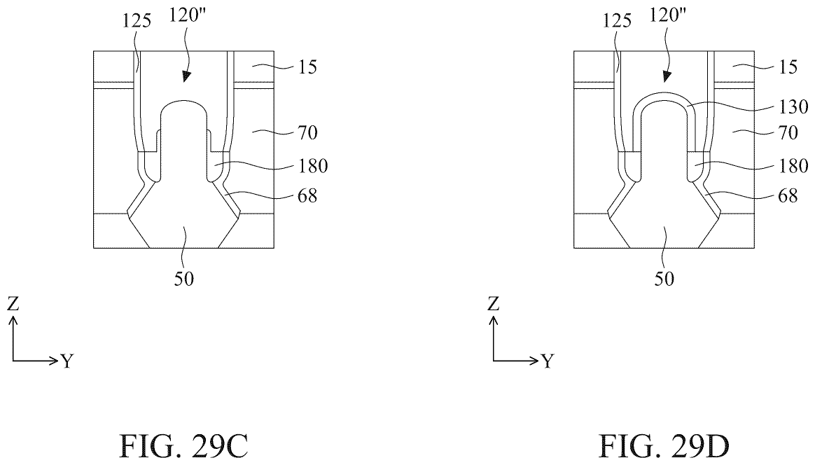

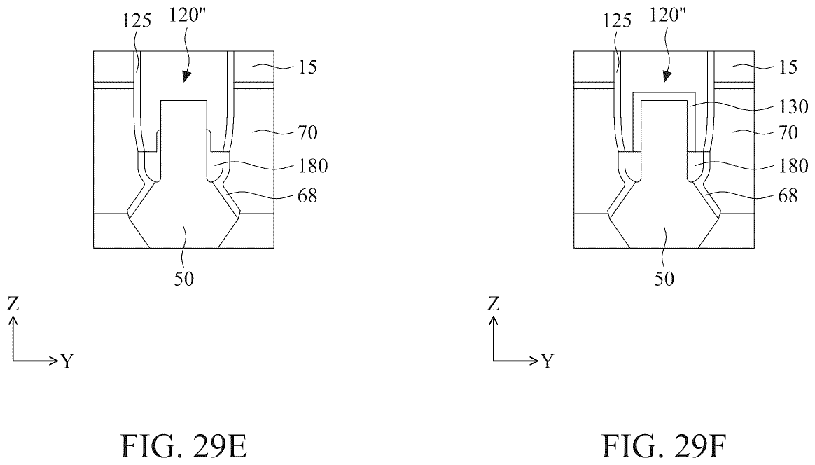

FIG. 29A and FIG. 29B respectively show a detailed isometric view and a detailed cross sectional view of one of the various stages of manufacturing a GAA FET semiconductor device according to an embodiment of the present disclosure. FIGS. 29C, 29D, 29E, and 29F show detailed cross sectional views of other embodiments of manufacturing a GAA FET semiconductor device according to an embodiment of the present disclosure. As shown in FIGS. 29A and 29B, a metal silicide layer 130 is formed in contact with the source/drain region 50. The silicide layer 130 is formed of the same materials and in the same manner as disclosed herein in reference to FIGS. 20A-20C. In some embodiments, the silicide layer 130 wraps around the upper surface and sidewalls of source/drain region 50, thereby increasing the contact surface area between the silicide layer 130 and the source/drain region 50. The silicide layer is concave shaped or M-shaped in some embodiments, as shown in FIGS. 29A and 29B. In some embodiments, the silicide layer wraps around the source/drain region in the Y-direction, but not in the X-direction. In other embodiments, where the upper surface of the source/drain region 50 is convex shaped before forming the silicide layer, as shown in FIG. 29C, the corresponding silicide will also be convex shaped when formed, as shown in FIG. 29D. In other embodiments, where the upper surface of the source/drain region 50 is flat before forming the silicide layer, as shown in FIG. 29E, the corresponding silicide will also be flat when formed, as shown in FIG. 29F. By proper selection of etchants and etching processes, a source/drain region having a convex upper surface or a flat upper surface can be formed in contrast to the concave upper surfaces illustrated herein.

In some embodiments, the metal silicide layer 130 is longer in the Y-direction by about 1 nm to about 20 nm than along the X-direction. In some embodiments, the metal silicide layer 130 is longer in the Y-direction by about 2 nm to about 15 nm than in the X-direction, and in other embodiments, the metal silicide layer 130 is longer in the Y-direction by about 5 nm to about 10 nm than along the X-direction. In some embodiments, the width W′ of the metal silicide layer 130 (see FIG. 31A) along the X-direction ranges from about 5 nm to about 40 nm and the length L′ of the metal silicide layer 130 (see FIG. 31A) along the Y-direction ranges from about 10 nm to about 80 nm. In some embodiments, a ratio of the length L′ of the metal silicide layer 130 along the Y-direction to the width W′ of the metal silicide layer along the X-direction ranges from about 2:1 to about 16:1, and in other embodiments, the ratio ranges from about 4:1 to about 8:1.

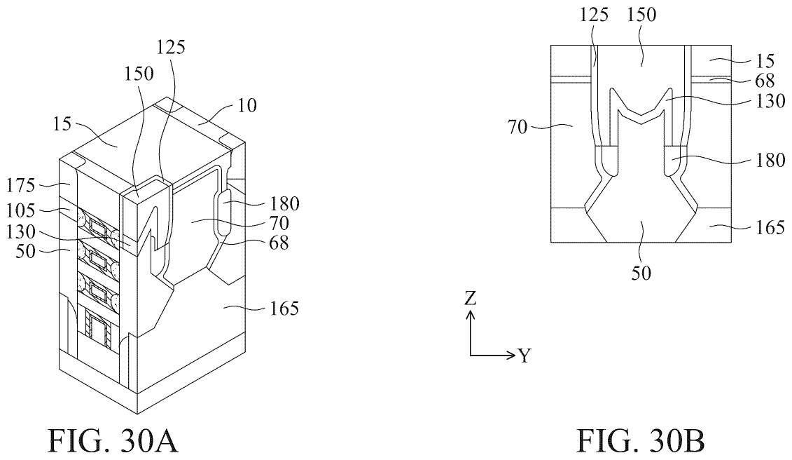

FIG. 30A and FIG. 30B respectively show a detailed isometric view and a detailed cross sectional view of one of the various stages of manufacturing a GAA FET semiconductor device according to an embodiment of the present disclosure. In FIGS. 30A and 30B a backside conductive contact 150 is formed in the trench. The conductive contact is formed of the same materials and in the same manner as the backside conductive contact disclosed herein in reference to the embodiment of FIGS. 21A-21C.

FIG. 31A and FIG. 31B respectively show a detailed isometric view and a detailed cross sectional view of one of the various stages of manufacturing a GAA FET semiconductor device according to an embodiment of the present disclosure. The lengths L, L′ and widths W, W′ of the trench and the metal silicide layer 130, respectively, are shown in FIG. 31A. FIG. 31B shows the thickness T of the silicide layer and the height H of the backside conductive contact 150. In some embodiments, the thickness T of the silicide layer 130 ranges from about 1 nm to about 10 nm. In some embodiments, the height H of the backside conductive contact 150 ranges from about 5 nm to about 40 nm.

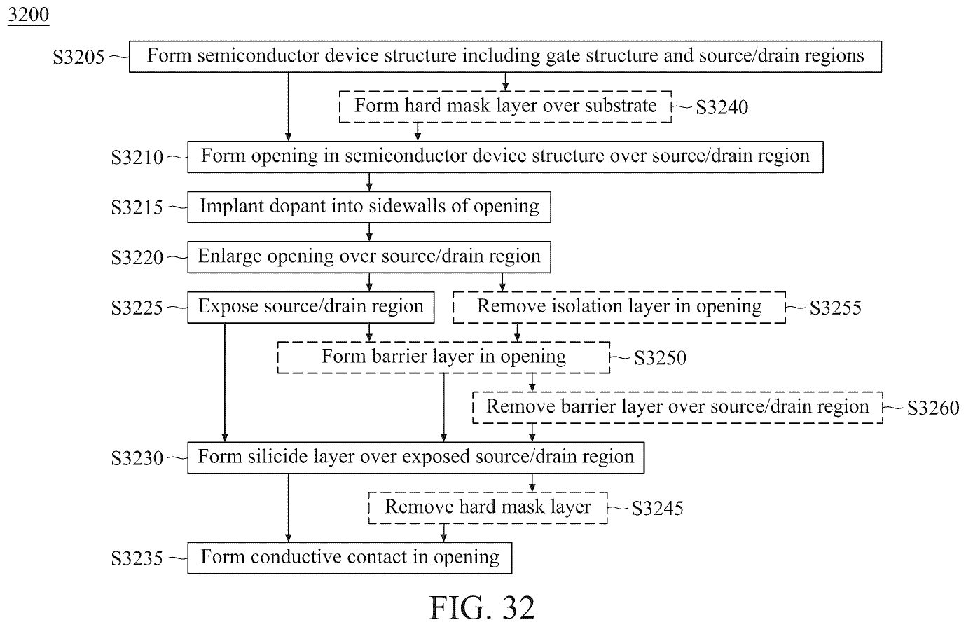

FIG. 32 shows a flow chart for a method 3200 of manufacturing a semiconductor device according to embodiments of the present disclosure. The method of manufacturing a semiconductor device includes an operation S3205 of forming a semiconductor device structure including a gate structure and source/drain regions 50 disposed over a substrate 10. The source/drain regions 50 are embedded in the semiconductor device structure. An opening 120 is formed in the semiconductor device structure over the source/drain region 50 in operation S3210. In operation S3215, a dopant is implanted into sidewalls of the opening 120′. Then, the opening 120″ is enlarged over the source/drain region 50 in operation S3220. The source/drain region is exposed in operation S3225. A silicide layer is subsequently formed over the exposed source/drain region in operation S3230, and a conductive contact is formed in the opening in operation S3235. In an embodiment, the method includes an operation S3240 of forming a hard mask layer over the substrate before forming the opening. In an embodiment, the method includes an operation S3245 of removing the hard mask layer after forming the silicide layer. In an embodiment, the method includes an operation S3250 of forming a barrier layer in the opening before forming the silicide layer, wherein the barrier layer is formed over the isolation layer. In an embodiment, the isolation layer in the opening is removed in operation S3255. In an embodiment, the barrier layer is removed in operation S3260.

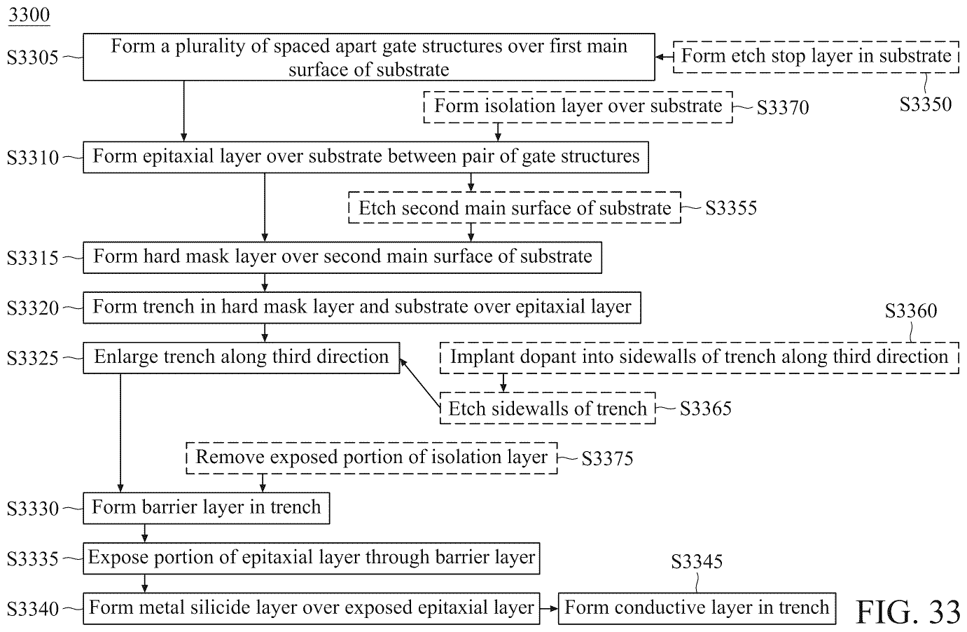

FIG. 33 shows a flow chart for a method 3300 of manufacturing a semiconductor device according to embodiments of the present disclosure. The method 3300 of manufacturing a semiconductor device includes an operation S3305 of forming a plurality of spaced apart gate structures over a first main surface of a substrate 10. The gate structures include a plurality of spaced apart semiconductor layers 25 stacked along a first direction extending from a surface of the substrate 10. An epitaxial layer 50 is formed over the substrate between a pair of gate structures along a second direction crossing the first direction in operation S3310. In operation S3315, a hard mask layer 135, 140 is formed over a second main surface of the substrate 10, wherein the second main surface is on an opposing side of the substrate from the first main surface. In operation S3320, a trench 120′ is formed in the hard mask layer 135, 140 and the substrate 10 over the epitaxial layer 50. The trench 120″ is enlarged along a third direction crossing the first direction and the second direction in operation S3325. Then in operation S3330, a barrier layer 125 is formed in the trench 120″ after enlarging the trench. A portion of the epitaxial layer 50 is exposed through the barrier layer in operation S3335. A metal silicide layer 130 is subsequently formed over the exposed epitaxial layer in operation S3340, and a conductive layer 150 is formed in the trench 120″ after forming the metal silicide layer 130 in operation S3345. In an embodiment, the method includes an operation S3350 of forming an etch stop layer 115 in the substrate 10 before forming the gate structures and the epitaxial layer 50. In an embodiment, the method includes an operation S3355 of etching the second main surface of the substrate thereby reducing a thickness of the substrate 10 before forming the hard mask layer 135, 140. In an embodiment, the enlarging the trench 120″ includes an operation S3360 of implanting a dopant into sidewalls of the trench along the third direction, and an operation S3365 of etching the sidewalls of the trench along the third direction using a wet etchant. In an embodiment, the method includes an operation S3370 of forming an isolation layer 105 over the substrate before forming the epitaxial layer, and the insolation layer is exposed in the trench 120′ by the forming the trench. In an embodiment, the method includes an operation S3375 of removing an exposed portion of the isolation layer 105 in the trench before forming the barrier layer.

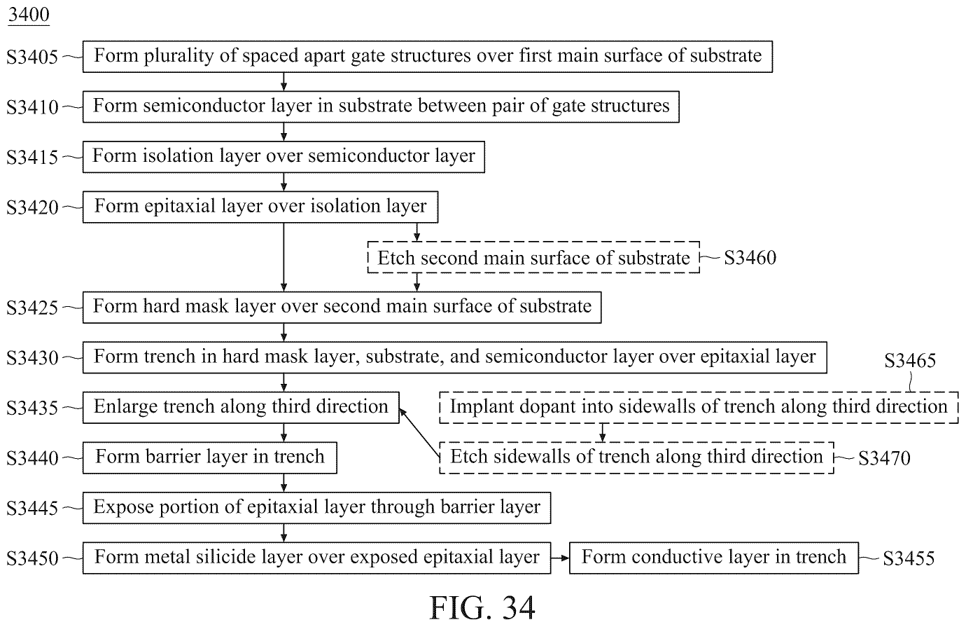

FIG. 34 shows a flow chart for a method 3400 of manufacturing a semiconductor device according to embodiments of the present disclosure. The method 3400 of manufacturing a semiconductor device includes an operation S3405 of forming a plurality of spaced apart gate structures over a first main surface of a substrate 10. The gate structures include a plurality of spaced apart first semiconductor layers 25 stacked along a first direction extending from a surface of the substrate. In operation S3410, a second semiconductor layer 110 is formed in the substrate 10 between a pair of gate structures along a second direction crossing the first direction. An isolation layer 105 is formed over the second semiconductor layer 110 in operation S3415. Then, in operation S3420, an epitaxial layer 50 is formed over the isolation layer 105. A hard mask layer 135, 140 is formed over a second main surface of the substrate 10 in operation S3425. The second main surface is on an opposing side of the substrate from the first main surface. In operation S3430, a trench 120″ is formed in the hard mask layer 135, 140, the substrate 10, and the second semiconductor layer 110 over the epitaxial layer 50. The trench 120″ is enlarged along a third direction crossing the first direction and the second direction in operation S3435. In operation S3440, a barrier layer 125 is formed in the trench after enlarging the trench 120″. In operation S3445, a portion of the epitaxial layer 50 is exposed through the barrier layer 125. Then, in operation S3450, a metal silicide layer 130 is formed over the exposed epitaxial layer 50 and a conductive layer 150 is formed in the trench 120″ after forming the metal silicide layer 130 in operation S3455. In an embodiment, the method includes an operation S3460 of etching the second main surface of the substrate thereby reducing a thickness of the substrate before forming the hard mask layer 135, 140. In an embodiment, the enlarging the trench includes: an operation S3465 of implanting a dopant into sidewalls of the trench along the third direction and an operation S3470 of etching the sidewalls of the trench along the third direction using a wet etchant.

Additional operations may be performed on the structure of FIGS. 21A-21C, 31A, and 31B, including forming additional insulating layers and metal wiring layers, including interconnects and vias formed over the disclosed structures. The disclosed structures may be part of a larger integrated circuit, including additional devices and components.

The increased surface area of the metal silicide to source/drain region contact provided by embodiments of the present disclosure enable a decrease in the electrical resistance of the semiconductor devices. Embodiments of the present disclosure provide an increase in the surface area of electrical contact between the backside via contact and the source/drain regions along a direction parallel to the extending gate structures. In some embodiments, a reduction of up to about 35% in the resistance of the backside via contact to the source/drain region can be achieved. Because the surface area of the silicide layer to source/drain region is not significantly increased along the direction between adjacent gate structures there is no increase in gate leakage current in embodiments of the disclosure.

It will be understood that not all advantages have been necessarily discussed herein, no particular advantage is required for all embodiments or examples, and other embodiments or examples may offer different advantages.

An embodiment of the disclosure is a method of manufacturing a semiconductor device including forming a semiconductor device structure including a gate structure and source/drain regions disposed over a substrate, wherein the source/drain regions are embedded in the semiconductor device structure. An opening is formed in the semiconductor device structure over the source/drain region. A dopant is implanted into sidewalls of the opening. The opening is enlarged over the source/drain region. The source/drain region is exposed. A silicide layer is formed over the exposed source/drain region, and a conductive contact is formed in the opening. In an embodiment, the opening is formed in the substrate. In an embodiment, the substrate is made of a semiconductor material. In an embodiment, the method includes forming a hard mask layer over the substrate before forming the opening. In an embodiment, the method includes removing the hard mask layer after forming the silicide layer. In an embodiment, an isolation layer is disposed between the substrate and the source/drain region. In an embodiment, the method includes forming a barrier layer in the opening before forming the silicide layer, wherein the barrier layer is formed over the isolation layer. In an embodiment, the method includes removing the isolation layer in the opening, forming a barrier layer in the opening after removing the isolation layer, and removing the barrier layer over the source/drain region.

Another embodiment of the disclosure is a method of manufacturing a semiconductor device including forming a plurality of spaced apart gate structures over a first main surface of a substrate. The gate structures include a plurality of spaced apart semiconductor layers stacked along a first direction extending from a surface of the substrate. An epitaxial layer is formed over the substrate between a pair of gate structures of the plurality of spaced apart gate structures along a second direction crossing the first direction. A hard mask layer is formed over a second main surface of the substrate, wherein the second main surface is on an opposing side of the substrate from the first main surface. A trench is formed in the hard mask layer and the substrate over the epitaxial layer. The trench is enlarged along a third direction crossing the first direction and the second direction. A barrier layer is formed in the trench after enlarging the trench. A portion of the epitaxial layer is exposed through the barrier layer. A metal silicide layer is formed over the exposed epitaxial layer, and a conductive layer is formed in the trench after forming the metal silicide layer. In an embodiment, the method includes forming an etch stop layer over the substrate before forming the gate structures and the epitaxial layer. In an embodiment, the substrate is made of silicon and the etch stop layer is made of SiGe. In an embodiment, the method includes etching the second main surface of the substrate thereby reducing a thickness of the substrate before forming the hard mask layer. In an embodiment, the enlarging the trench includes implanting a dopant into sidewalls of the trench along the third direction, and etching the sidewalls of the trench along the third direction using a wet etchant. In an embodiment, the method includes forming an isolation layer over the substrate before forming the epitaxial layer, and the isolation layer is exposed in the trench by the forming the trench. In an embodiment, the method includes removing an exposed portion of the isolation layer in the trench before forming the barrier layer.

Another embodiment of the disclosure is a method of manufacturing a semiconductor device including forming a plurality of spaced apart gate structures over a first main surface of a substrate, wherein the gate structures include a plurality of spaced apart semiconductor nanosheets stacked along a first direction extending from a surface of the substrate. A semiconductor layer is formed in the substrate between a pair of gate structures of the plurality of spaced apart gate structures along a second direction crossing the first direction. An isolation layer is formed over the semiconductor layer. An epitaxial layer is formed over the isolation layer. A hard mask layer is formed over a second main surface of the substrate, wherein the second main surface is on an opposing side of the substrate from the first main surface. A trench is formed in the hard mask layer, the substrate, and the semiconductor layer over the epitaxial layer. The trench is enlarged along a third direction crossing the first direction and the second direction. A barrier layer is formed in the trench after enlarging the trench. A portion of the epitaxial layer is exposed through the barrier layer. A metal silicide layer is formed over the exposed epitaxial layer and a conductive layer is formed in the trench after forming the metal silicide layer. In an embodiment, the semiconductor layer has a higher selectivity to an etchant used to form the trench than the substrate. In an embodiment, the substrate includes silicon and the semiconductor layer comprises SiGe. In an embodiment, the method includes etching the second main surface of the substrate thereby reducing a thickness of the substrate before forming the hard mask layer. In an embodiment, the enlarging the trench includes: implanting a dopant into sidewalls of the trench along the third direction and etching the sidewalls of the trench along the third direction using a wet etchant.

Another embodiment of the disclosure is a semiconductor device including a gate structure disposed over a substrate and a source/drain structure disposed over the substrate adjacent the gate structure along a first direction. A metal silicide layer is disposed under the source/drain structure. The metal silicide layer is in contact with opposing sidewall surfaces of the source/drain structure and a surface connecting the sidewall surfaces as seen in cross section. A conductive contact is disposed under the metal silicide layer. In an embodiment, the metal silicide layer is convex-shaped, concave shaped, or M-shaped as seen in cross section. In an embodiment, the conductive contact is disposed in the substrate. In an embodiment, the gate structure comprises a stack of spaced-apart semiconductor layers. In an embodiment, the semiconductor layers are nanosheets. In an embodiment, the gate structure comprises a gate electrode layer wrapping around each of the spaced-apart semiconductor layers. In an embodiment, the metal silicide layer is longer along a second direction crossing the first direction than along the first direction. In an embodiment, a ratio of a length of the metal silicide layer along the second direction to a width of the metal silicide layer along the first direction ranges from 2:1 to 16:1.

Another embodiment of the disclosure is a semiconductor device including a plurality of spaced-apart gate structures arranged over a substrate along a first direction. A source/drain structure is disposed between each adjacent pair of spaced-apart gate structures of the plurality of spaced-apart gate structures along the first direction. In an embodiment, a trench is disposed in the substrate exposing a portion of the source/drain structure. A length of the trench along a second direction crossing the first direction is longer than a width of the trench along the first direction. A metal silicide layer is disposed under the source/drain structure in the trench and a conductive contact layer is disposed under the metal silicide layer and fills the trench. In an embodiment, a ratio of a length of the trench along the second direction to a width of the trench along the first direction ranges from 2:1 to 16:1. In an embodiment, the metal silicide layer is convex-shaped, concave shaped, or M-shaped as seen in cross section. In an embodiment, the gate structures includes a stack of spaced-apart semiconductor nanostructures arranged along a third direction crossing the first and second directions. In an embodiment, the gate structures include a gate electrode layer wrapping around each of the spaced-apart semiconductor nanostructures. In an embodiment, the semiconductor device includes a barrier layer disposed on sidewalls of the trench. In an embodiment, the metal silicide layer is selected from the group consisting of a titanium silicide, a molybdenum silicide, a ruthenium silicide, a tungsten silicide, a titanium silicide, a rhodium silicide, a niobium silicide, an iridium silicide, a yttrium silicide, an antimony silicide, a scandium silicide, a zirconium silicide, and combinations thereof.

Another embodiment of the disclosure is a semiconductor device including a plurality of spaced-apart gate-all-around structures arranged over a substrate along a first direction. A source/drain structure is disposed between each adjacent pair of spaced-apart gate structures of the plurality of spaced-apart gate structures along the first direction. A backside conductive contact passes through the substrate and contacts the source/drain structure through an intervening metal silicide layer. The metal silicide layer contacts opposing sidewalls of the source/drain structure and a surface of the source/drain structure connects the opposing sidewalls as seen in cross section. In an embodiment, a length of the metal silicide layer along a second direction crossing the first direction is longer than a width of the metal silicide layer along the first direction. In an embodiment, a ratio of the length of the metal silicide layer along the second direction to the width of the metal silicide layer along the first direction ranges from 2:1 to 16:1. In an embodiment, the metal silicide layer is convex-shaped, concave shaped, or M-shaped as seen in cross section. In an embodiment, the semiconductor device includes a barrier layer disposed between the substrate and the conductive contact.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of spaced-apart gate structures arranged over a substrate along a first direction;
a source/drain structure disposed between each adjacent pair of spaced-apart gate structures of the plurality of spaced-apart gate structures along the first direction;
a trench disposed in the substrate exposing a portion of the source/drain structure,
wherein a length of the trench along a second direction crossing the first direction is longer than a width of the trench along the first direction;
a metal silicide layer disposed under the source/drain structure in the trench; and
a conductive contact layer disposed under the metal silicide layer and filling the trench.

2. The semiconductor device of claim 1, wherein a ratio of a length of the trench along the second direction to a width of the trench along the first direction ranges from 2:1 to 16:1.

3. The semiconductor device of claim 1, wherein the metal silicide layer is convex-shaped, concave shaped, or M-shaped as seen in cross section.

4. The semiconductor device of claim 1, wherein the gate structures comprise a stack of spaced-apart semiconductor nanostructures arranged along a third direction crossing the first and second directions.

5. The semiconductor device of claim 4, wherein the gate structures comprise a gate electrode layer wrapping around each of the spaced-apart semiconductor nanostructures.

6. The semiconductor device of claim 1, further comprising a barrier layer disposed on sidewalls of the trench.

7. The semiconductor device of claim 1, wherein the metal silicide layer is selected from the group consisting of a titanium silicide, a molybdenum silicide, a ruthenium silicide, a tungsten silicide, a titanium silicide, a rhodium silicide, a niobium silicide, an iridium silicide, a yttrium silicide, an antimony silicide, a scandium silicide, a zirconium silicide, and combinations thereof.

8. A semiconductor device, comprising:
a plurality of spaced-apart gate-all-around structures arranged over a substrate along a first direction;
a source/drain structure disposed between each adjacent pair of spaced-apart gate structures of the plurality of spaced-apart gate structures along the first direction; and
a backside conductive contact passing through the substrate and contacting the source/drain structure through an intervening metal silicide layer,
wherein the metal silicide layer contacts opposing sidewalls of the source/drain structure and a surface of the source/drain structure connecting the opposing sidewalls as seen in cross section.

9. The semiconductor device of claim 8, wherein a length of the metal silicide layer along a second direction crossing the first direction is longer than a width of the metal silicide layer along the first direction.

10. The semiconductor device of claim 9, wherein a ratio of the length of the metal silicide layer along the second direction to the width of the metal silicide layer along the first direction ranges from 2:1 to 16:1.

11. The semiconductor device of claim 8, wherein the metal silicide layer is convex-shaped, concave shaped, or M-shaped as seen in cross section.

12. The semiconductor device of claim 8, further comprising a barrier layer disposed between the substrate and the conductive contact.

13. A method of manufacturing a semiconductor device, comprising:
forming a plurality of spaced apart gate structures over a first main surface of a substrate,
wherein the gate structures include a plurality of spaced apart semiconductor nanosheets stacked along a first direction extending from a surface of the substrate;
forming a semiconductor layer in the substrate between a pair of gate structures of the plurality of spaced apart gate structures along a second direction crossing the first direction;
forming an isolation layer over the semiconductor layer;
forming an epitaxial layer over the isolation layer;
forming a hard mask layer over a second main surface of the substrate, wherein the second main surface is on an opposing side of the substrate from the first main surface;
forming a trench in the hard mask layer, the substrate, and the semiconductor layer over the epitaxial layer;
enlarging the trench along a third direction crossing the first direction and the second direction;
forming a barrier layer in the trench after enlarging the trench;
exposing a portion of the epitaxial layer through the barrier layer;
forming a metal silicide layer over the exposed epitaxial layer; and
forming a conductive layer in the trench after forming the metal silicide layer.

14. The method according to claim 13, wherein the semiconductor layer has a higher selectivity to an etchant used to form the trench than the substrate.

15. The method according to claim 13, wherein the substrate comprises silicon and the semiconductor layer comprises SiGe.

16. The method according to claim 13, further comprising etching the second main surface of the substrate thereby reducing a thickness of the substrate before forming the hard mask layer.

17. The method according to claim 13, wherein the enlarging the trench comprises:
implanting a dopant into sidewalls of the trench along the third direction; and
etching the sidewalls of the trench along the third direction using a wet etchant.

18. The method according to claim 13, wherein the gate structures comprise a gate electrode layer wrapping around the spaced apart semiconductor nanosheets.

19. The method according to claim 13, wherein the metal silicide layer is longer along the second direction than along the third direction.

20. The method according to claim 19, wherein a ratio of a length of the metal silicide layer along the second direction to a width of the metal silicide layer along the third direction ranges from 2:1 to 16:1.
